(19) United States
(12) Patent Application Publication
(10) Pub. No.: US 2024/0376342 A1
(43) Pub. Date: Nov. 14, 2024

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventor: Seil CHOI, Suwon-si (KR)

(21) Appl. No.: 18/426,744

(22) Filed: Jan. 30, 2024

(30) Foreign Application Priority Data
May 8, 2023 (KR) 10-2023-0059309

(51) Int. Cl. C09D 173/00; G03F 7/16; H01L 21/027; H01L 21/308; H01L 21/311; H01L 21/3213

(52) U.S. Cl. CPC C09D 173/00; G03F 7/168; H01L 21/0272; H01L 21/3081; H01L 21/31144; H01L 21/32139

(57) ABSTRACT

A hardmask composition, a hardmask layer manufactured from the hardmask composition, and a method of forming a pattern or patterns using a hardmask layer manufactured from the hardmask composition, the hardmask composition includes a polymer that includes a structural unit represented by Chemical Formula 1; and a solvent:

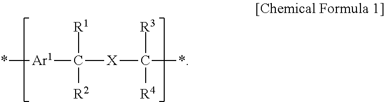

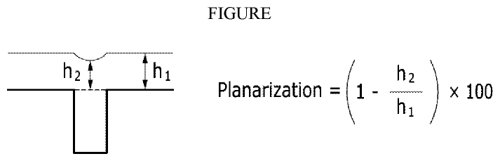

### CROSS-REFERENCE TO RELATED APPLICATION

This application claims priority to and the benefit of Korean Patent Application No. 10-2023-0059309 filed in the Korean Intellectual Property Office on May 8, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may utilize effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

Nowadays, according to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

### SUMMARY

The embodiments may be realized by providing a hardmask composition including a polymer including a structural unit represented by Chemical Formula 1; and a solvent:

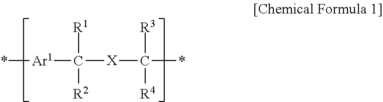

wherein, in Chemical Formula 1, Ar¹ is a substituted or unsubstituted C6 to C30 aromatic hydrocarbon group, a substituted or unsubstituted C3 to C30 heteroaromatic group, or a group where two or more substituted or unsubstituted C6 to C30 aromatic hydrocarbon groups, two or more substituted or unsubstituted C3 to C30 heteroaromatic groups, or a combination thereof are linked by a single bond or a substituted or unsubstituted C1 to C10 alkylene group, R¹ to R⁴ are each independently hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic hydrocarbon group, or a combination thereof, provided that R¹ and R² are not hydrogen at the same time and R³ and R⁴ are not hydrogen at the same time, and X is a group represented by Chemical Formula 2:

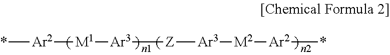

in Chemical Formula 2, Ar² and Ar³ are each independently a substituted or unsubstituted C6 to C30 aromatic hydrocarbon group, M¹ and M² are each independently —O—, —S—, —S(═O)—, —SO₂—, —NR^{a-}, in which R^{a} is hydrogen, a substituted or unsubstituted C1 to C10 alkyl group, or a substituted or unsubstituted C6 to C20 aryl group, or a combination thereof, Z is a group of Group 1, n1 is an integer of 1 to 30, n2 is 0 or 1, and * is a linking point:

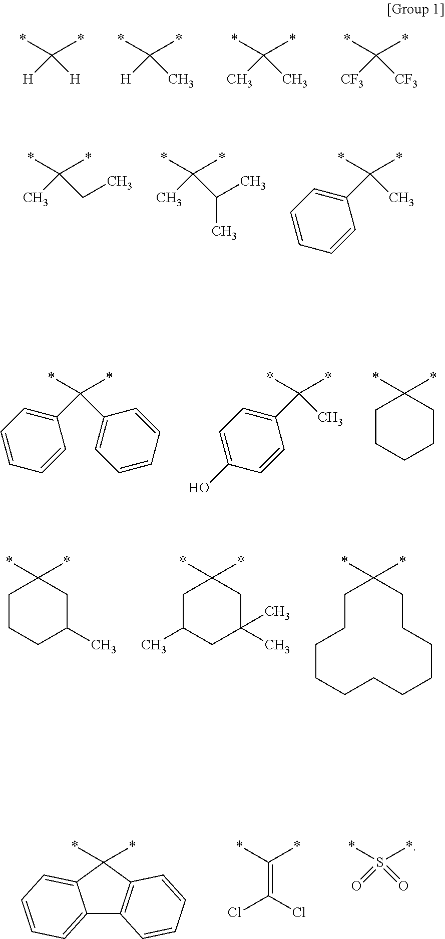

Ar¹ of Chemical Formula 1 may be a substituted or unsubstituted group of a moiety of Group 2:

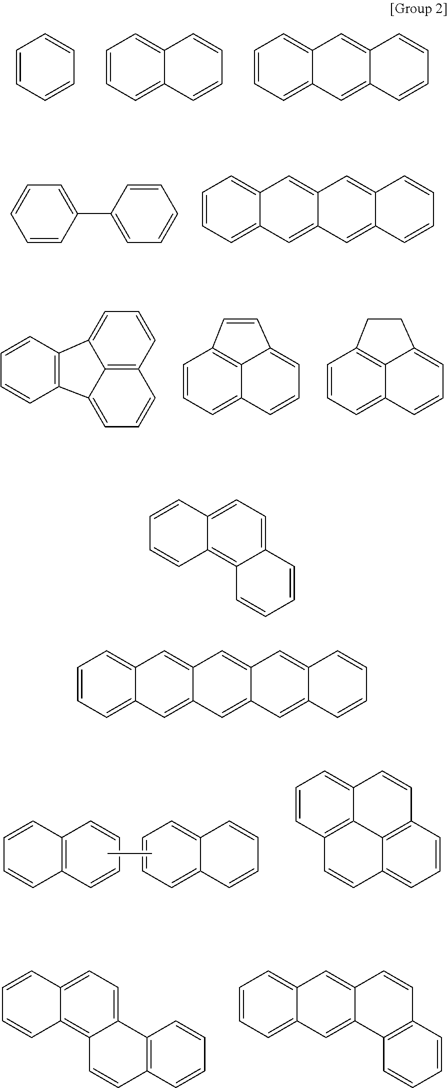

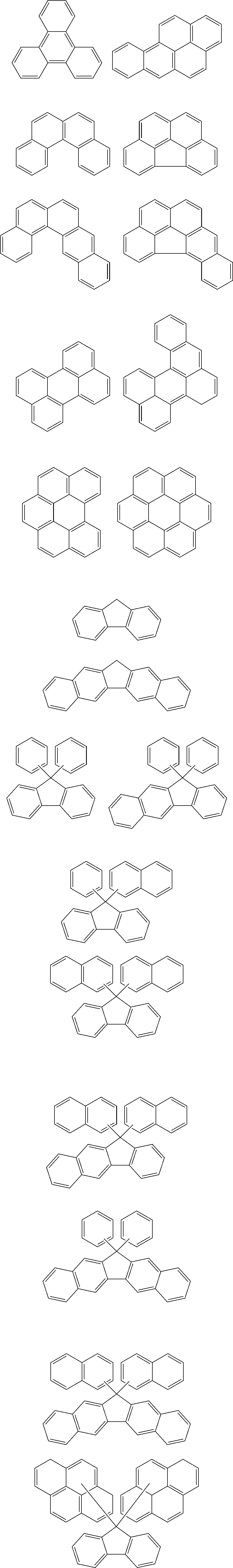

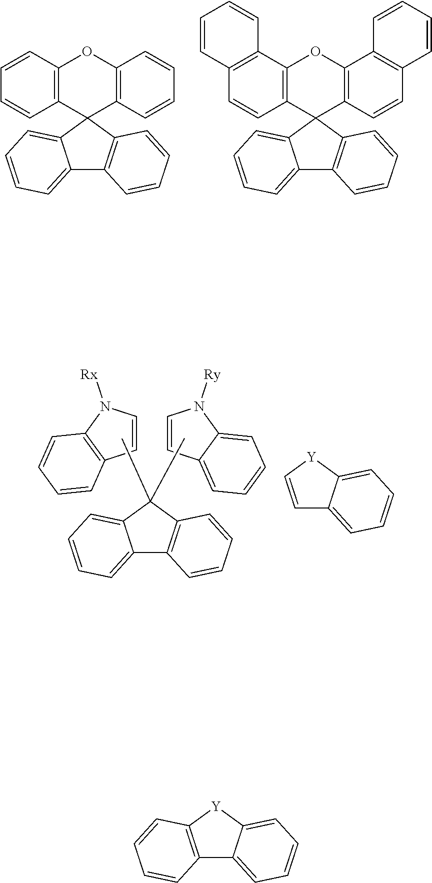

in Group 2, Y may be —O—, —S—, or —NR^{b-}, in which R^{b} may be hydrogen, a substituted or unsubstituted C1 to C10 alkyl group, or a substituted or unsubstituted C6 to C20 aryl group, and Rx and Ry may each independently be hydrogen, deuterium, a halogen atom, a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C20 aryl group.

Ar¹ of Chemical Formula 1 may be substituted C6 to C30 aromatic hydrocarbon group, a substituted C3 to C30 heteroaromatic group, or a group where two or more substituted C6 to C30 aromatic hydrocarbon groups, two or more substituted C3 to C30 heteroaromatic groups, or a combination thereof are linked by a single bond or a substituted or unsubstituted C1 to C10 alkylene group, and a substituent of the substituted C6 to C30 aromatic hydrocarbon group, a substituted C3 to C30 heteroaromatic group, or a group where two or more substituted C6 to C30 aromatic hydrocarbon groups, two or more substituted C3 to C30 heteroaromatic groups, or a combination thereof are linked by a single bond or a substituted or unsubstituted C1 to C10 alkylene group may include a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, a substituted or unsubstituted C1 to C20 heteroalkyl group, a substituted or unsubstituted C3 to C20 heteroaryl group, or a combination thereof.

R¹ to R⁴ of Chemical Formula 1 may be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, provided that R¹ and R² are not hydrogen at the same time and R³ and R⁴ are not hydrogen at the same time.

In Chemical Formula 1, R¹ and R³ may be the same and R² and R⁴ may be the same.

Ar¹ of Chemical Formula 1 may be a substituted or unsubstituted group of a moiety of Group 2-1, and R¹ to R⁴ may be hydrogen, deuterium, a substituted or unsubstituted C1 to C10 alkyl group, a substituted or unsubstituted C6 to C16 aryl group, or a combination thereof, provided that R¹ and R² are not hydrogen at the same time and R³ and R⁴ are not hydrogen at the same time:

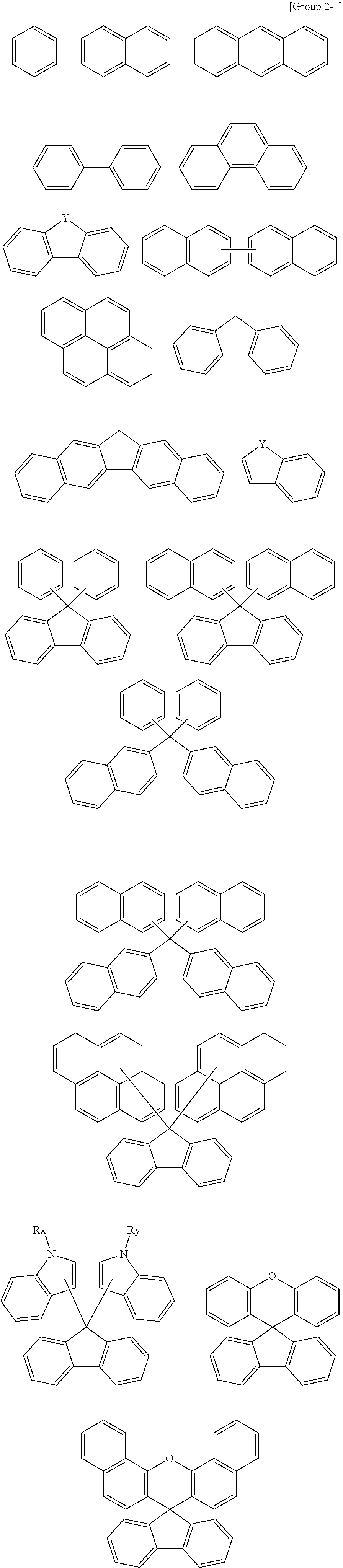

in Group 2-1, Y may be —O—, —S—, or —NR^{b-}, in which R^{b} may be hydrogen, a substituted or unsubstituted C1 to C10 alkyl group, or a substituted or unsubstituted C6 to C20 aryl group, and Rx and Ry may be hydrogen, deuterium, a substituted or unsubstituted C1 to C10 alkyl group, or a substituted or unsubstituted C6 to C20 aryl group.

Ar² and Ar³ of Chemical Formula 2 may be a substituted or unsubstituted C6 to C30 aromatic hydrocarbon group of a moiety of Group 3:

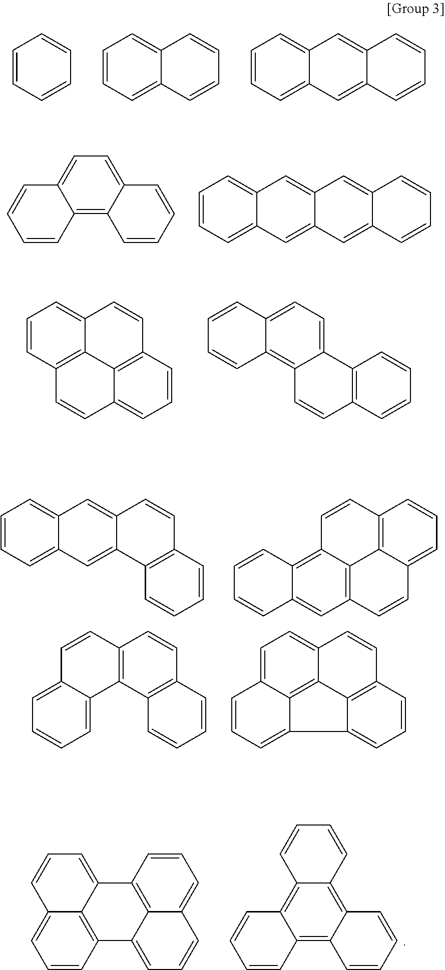

Ar² and Ar³ of Chemical Formula 2 may be a substituted or unsubstituted benzene group, a substituted or unsubstituted naphthalene group, a substituted or unsubstituted phenanthrene group, a substituted or unsubstituted anthracene group, or a substituted or unsubstituted pyrene group.

Ar² and Ar³ of Chemical Formula 2 may be substituted or unsubstituted benzene group, substituted or unsubstituted naphthalene group, or substituted or unsubstituted pyrene group, M¹ and M² may be —O—, n1 may be an integer of 1 to 5, and Z may be a group of Group 1-1:

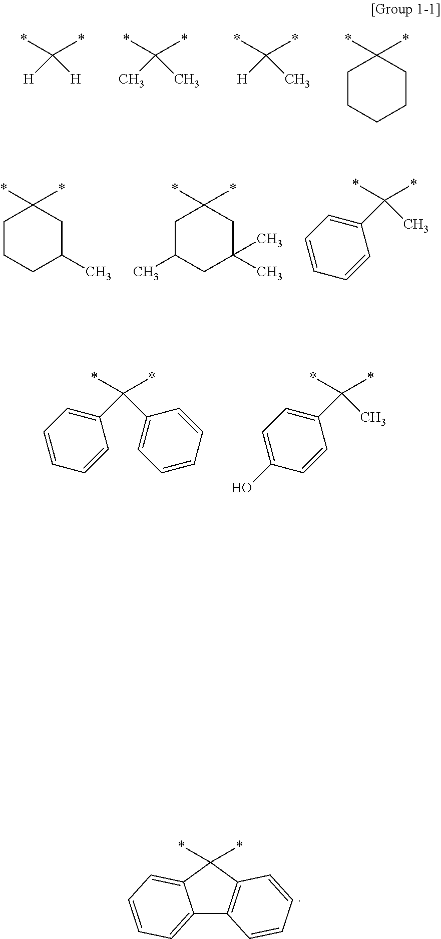

In Chemical Formula 2, n1 and n2 may be 1.

In Chemical Formula 2, n1 may be an integer of 1 to 5, and n2 may be 0.

The structural unit represented by Chemical Formula 1 may be represented by one of Chemical Formula 1-1 to Chemical Formula 1-4:

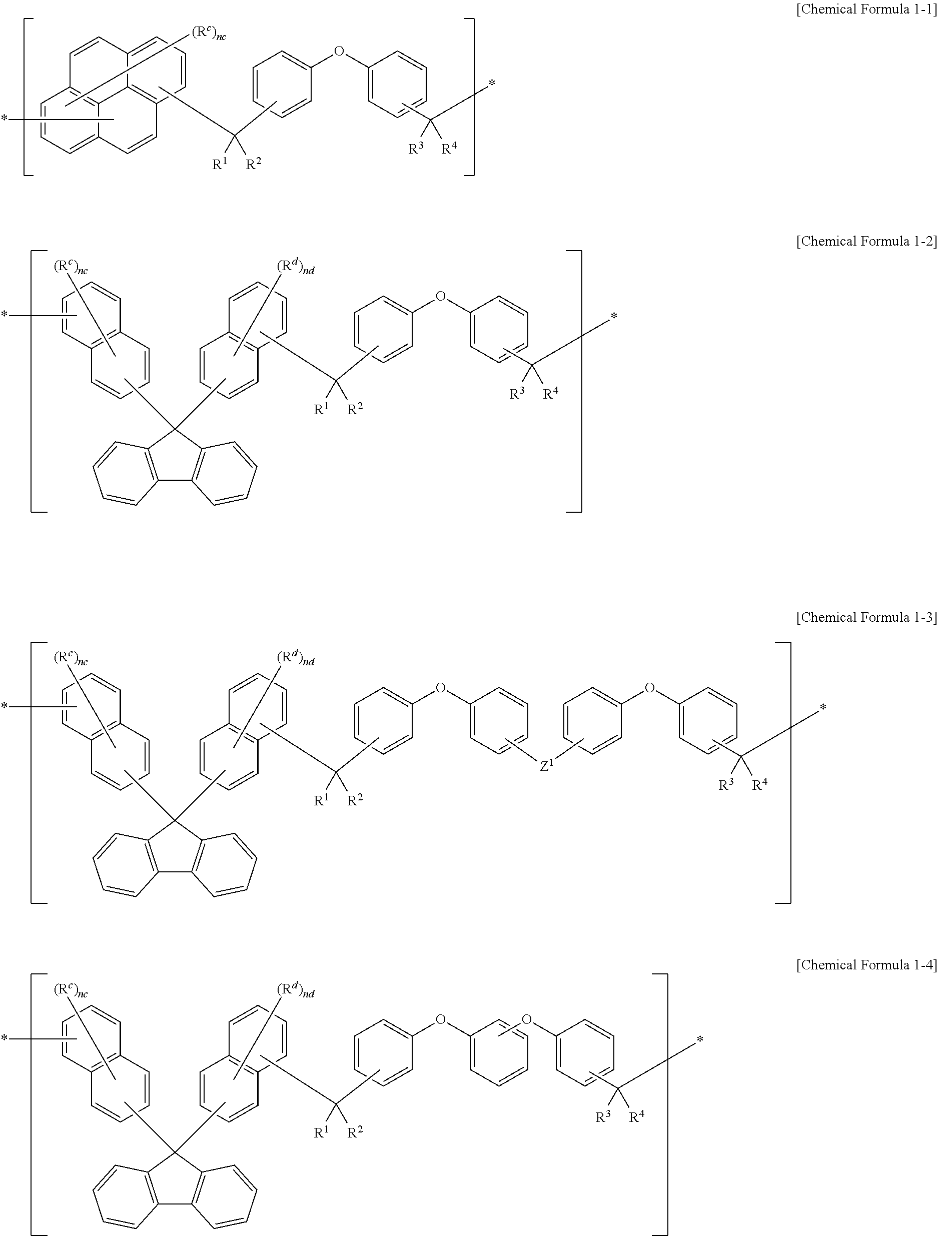

in Chemical Formula 1-1 to Chemical Formula 1-4, R¹ to R⁴ may be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, provided that R¹ and R² are not hydrogen at the same time and R³ and R⁴ are not hydrogen at the same time, Z¹ may be a group of Group 1, R^{c} and R^{d} may be a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C6 to C20 aryl group, a substituted or unsubstituted C3 to C20 heteroaryl group, or a combination thereof, and nc and nd may be an integer of 0 to 6:

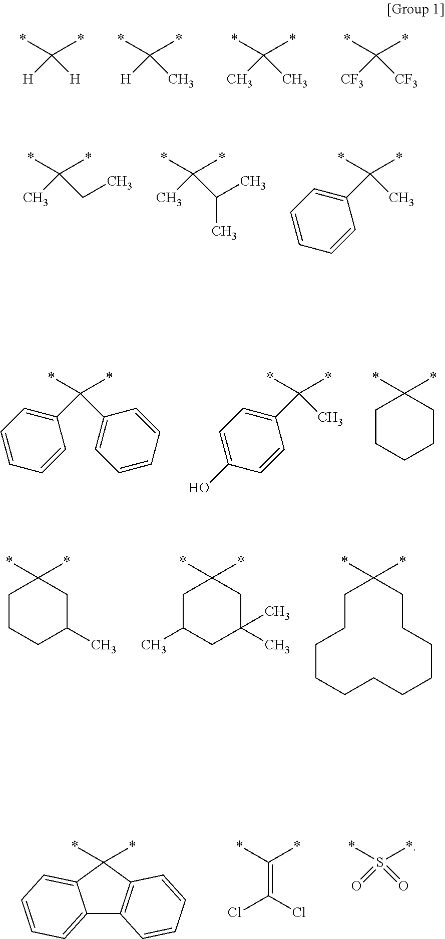

The structural unit represented by Chemical Formula 1 may be represented by one of Chemical Formula 1-5 to Chemical Formula 1-13:

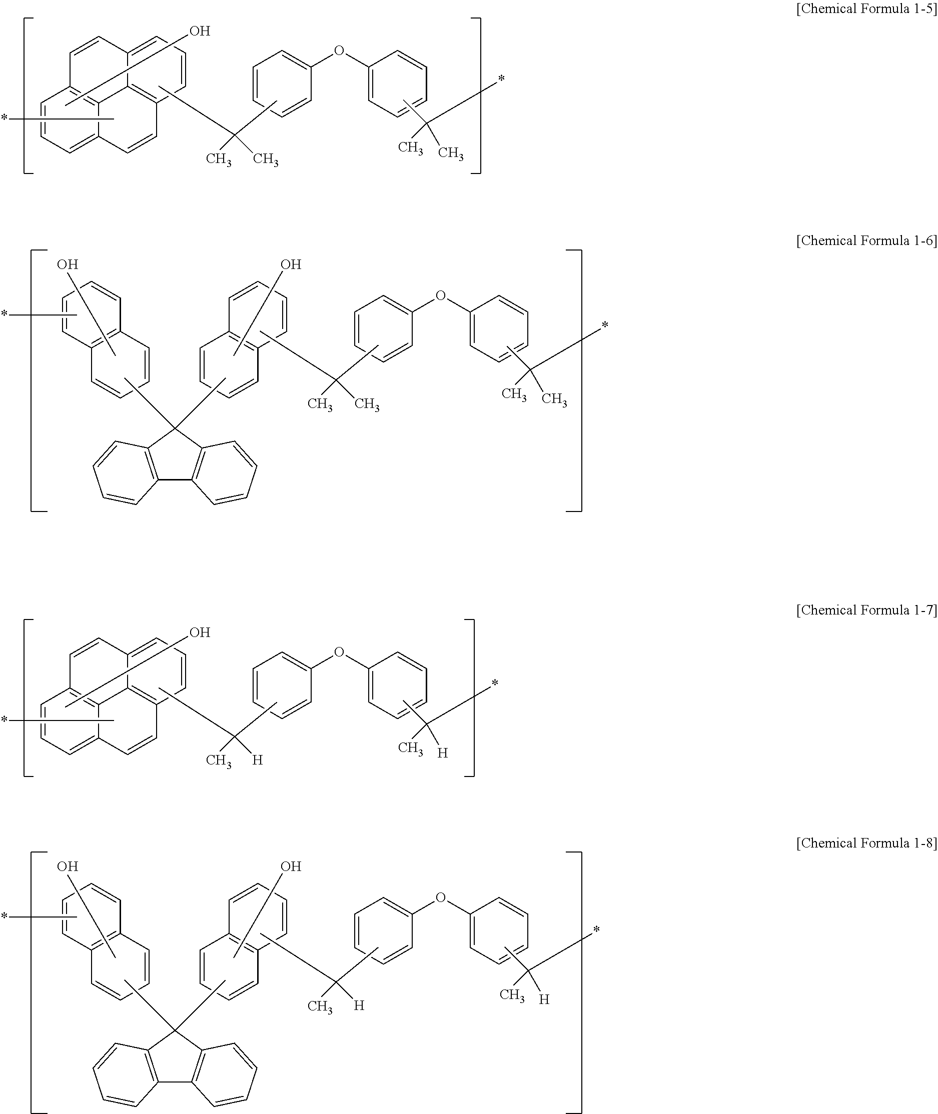

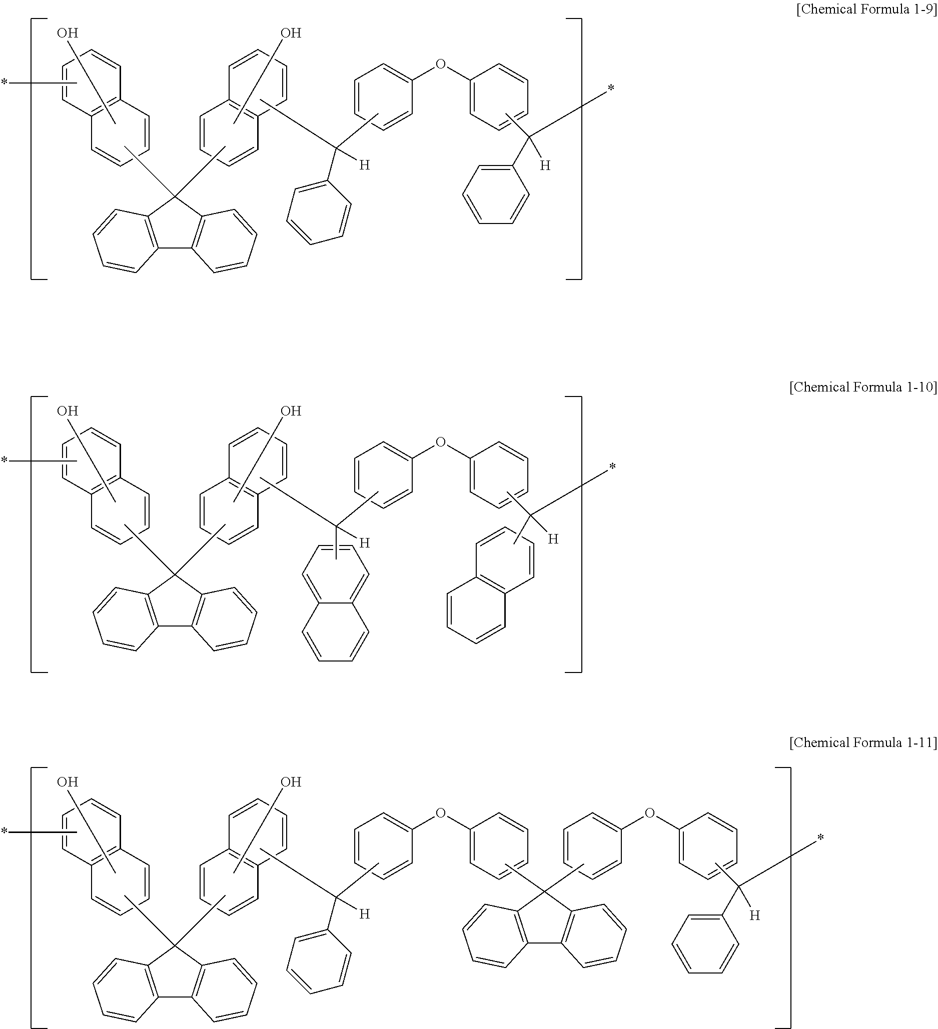

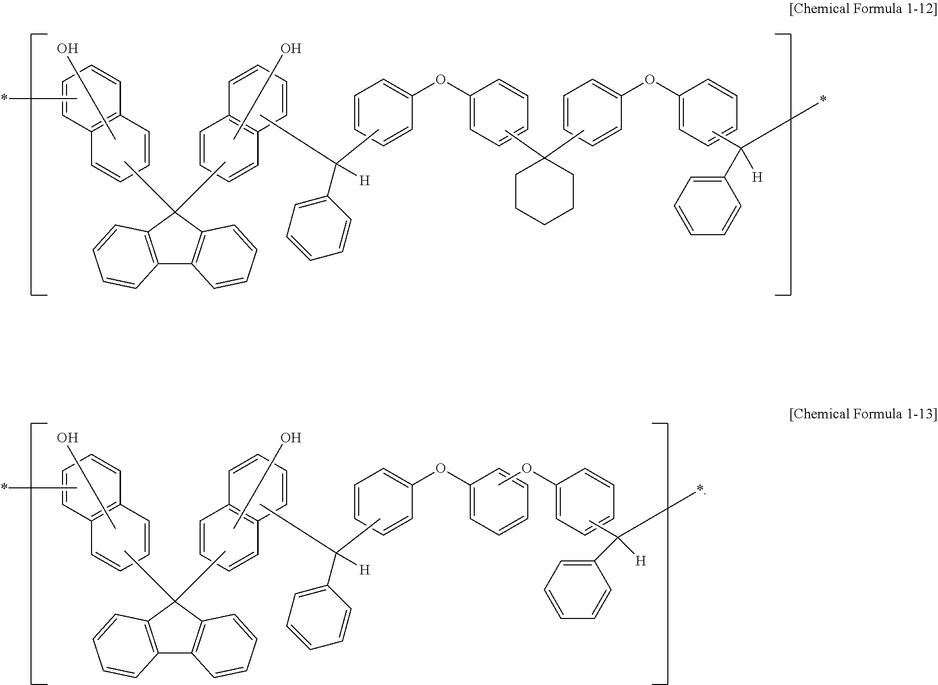

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may be propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer comprising a cured product of the hardmask composition according to an embodiment.

The embodiments may be realized by providing a method of forming patterns, the method including providing a material layer on a substrate; applying the hardmask composition according to an embodiment to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### BRIEF DESCRIPTION OF THE DRAWING

Features will become apparent to those of skill in the art by describing in detail exemplary embodiments with reference to the attached drawing in which:

the FIGURE shows Calculation Equation for evaluating planarization characteristics.

### DETAILED DESCRIPTION

Example embodiments will now be described more fully hereinafter with reference to the accompanying drawings; however, they may be embodied in different forms and should not be construed as limited to the embodiments set forth herein.

Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B. As used herein, unless otherwise defined, * is a linking point.

In addition, adjacent two substituents of the substituted halogen atom (F, Br, C1, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon” refers to a group including at least one hydrocarbon aromatic moiety, and includes a form in which hydrocarbon aromatic moieties are linked by a single bond, a non-aromatic fused ring form in which hydrocarbon aromatic moieties are fused directly or indirectly, or a combination thereof as well as a non-fused aromatic hydrocarbon ring or a condensed aromatic hydrocarbon ring.

More specifically, the substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

As used herein, when a definition is not otherwise provided, “hetero” refers to one including at least one heteroatom selected from N, O, S, Se, and P.

As used herein, when a definition is not otherwise provided, “heteroaromatic group” refers to a group including at least one hetero atom selected from N, O, S, Se, and P within an aromatic hydrocarbon ring.

As used herein, the polymer may include both an oligomer and a polymer.

Unless otherwise specified in the present specification, the “molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include, e.g., a polymer including a structural unit represented by Chemical Formula 1, and a solvent.

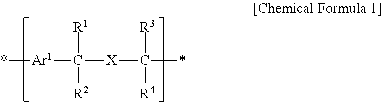

In Chemical Formula 1, Ar¹ may be or may include, e.g., a substituted or unsubstituted C6 to C30 aromatic hydrocarbon group, a substituted or unsubstituted C3 to C30 heteroaromatic group, or a group in which two or more substituted or unsubstituted C6 to C30 aromatic hydrocarbon rings, two or more substituted or unsubstituted C3 to C30 heteroaromatic rings, or a combination thereof are linked by a single bond or a substituted or unsubstituted C1 to C10 alkylene group. In an implementation, substituents of the substituted C1 to C10 alkylene group may be separate or may be linked or fused to form a structure that includes at least one ring.

R¹ to R⁴ may each independently be or include, e.g., hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic hydrocarbon group, or a combination thereof. In an implementation, R¹ and R² may not be hydrogen at the same time and R³ and R⁴ may not be hydrogen at the same time.

X may be, e.g., a group represented by Chemical Formula 2.

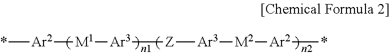

In Chemical Formula 2, Ar² and Ar³ may each independently be or include, e.g., a substituted or unsubstituted C6 to C30 aromatic hydrocarbon group.

M¹ and M² may each independently be or include, e.g., —O—, —S—, —S(═O)—, —SO₂—, —NR^{a-}, in which R^{a} is hydrogen, a substituted or unsubstituted C1 to C10 alkyl group, or a substituted or unsubstituted C6 to C20 aryl group, or a combination thereof,
Z may be, e.g., a group of Group 1.
n1 may be, e.g., an integer of 1 to 30.
n2 may be, e.g., 0 or 1.
* is a linking point:

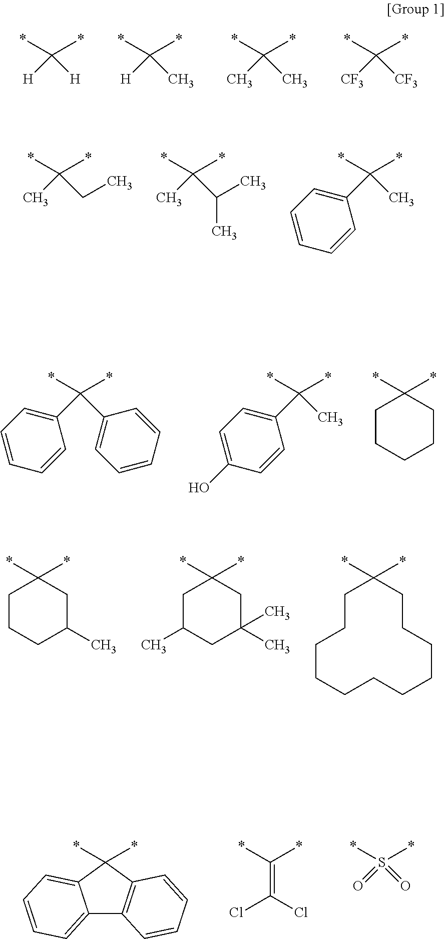

In an implementation, Chemical Formula 1 may include a large aromatic hydrocarbon group and thus may increase a carbon content in the polymer. Accordingly, a hardmask layer formed of the composition may help secure excellent etch resistance.

In an implementation, Chemical Formula 1, in which at least one of the R¹ and R² is not hydrogen, at least one of R³ and R⁴ is not hydrogen, may include a tertiary carbon or a quaternary carbon, thereby suppressing an oxidation reaction of the composition including the polymer as well as improving solubility of the polymer in solvents may not only be improved and resultantly, improving gap-filling characteristics and planarization characteristics of a hardmask layer.

In an implementation, Chemical Formula 1 may have X, e.g., a group represented by Chemical Formula 2, which may help bring about a flexible structure in the structural unit of the polymer, thereby improving the solubility of the polymer in solvents and simultaneously, improving the gap-filling characteristics and the planarization characteristics of the hardmask layer formed of the composition including the polymer.

In an implementation, Ar¹ of Chemical Formula 1 may be, e.g., a substituted or unsubstituted group of a moiety of Group 2. In an implementation, Ar¹ of Chemical Formula 1 may be, e.g., a substituted or unsubstituted group of a moiety of Group 2-1.

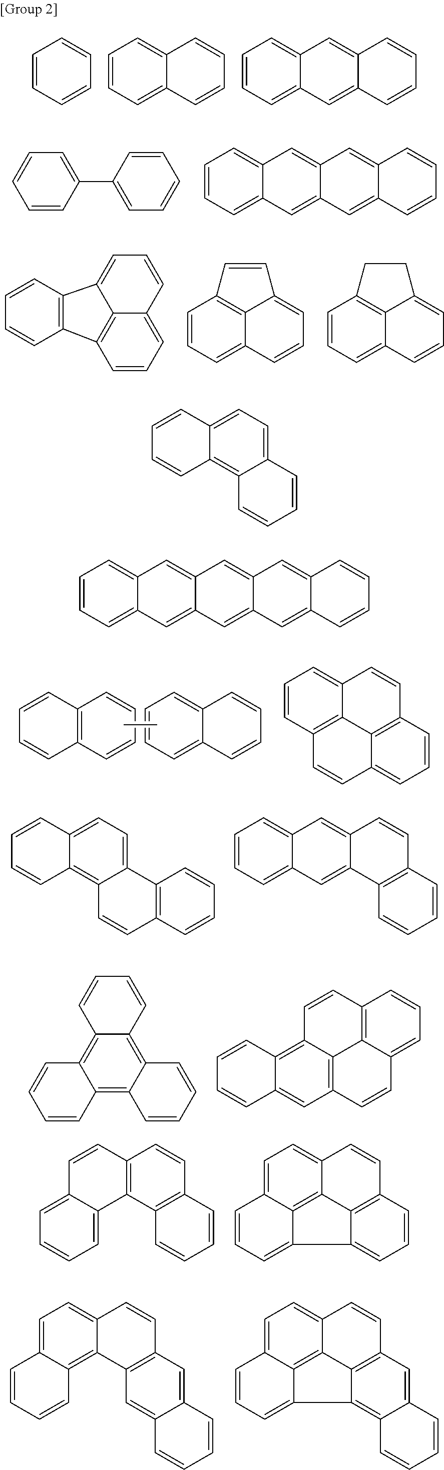

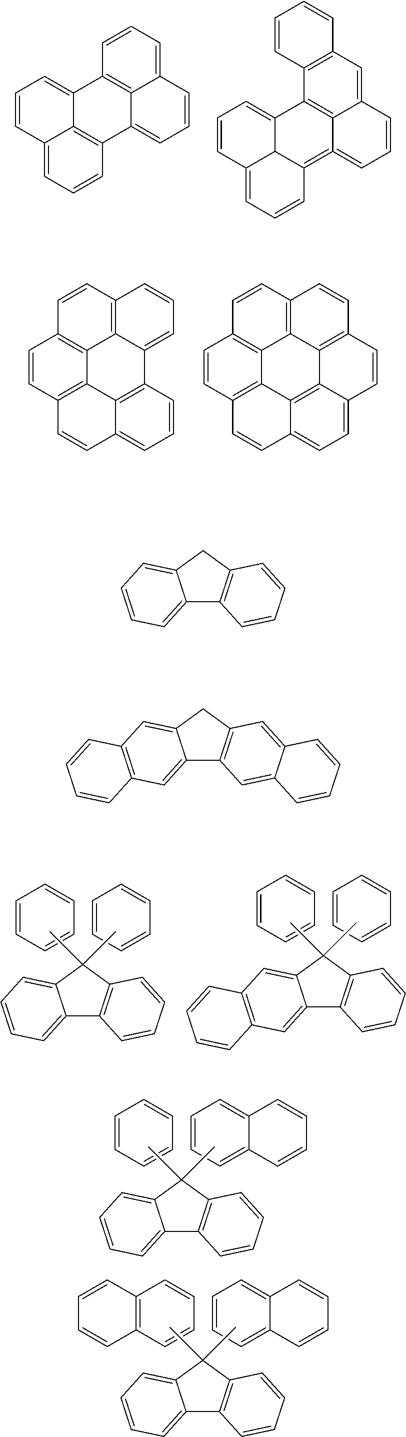

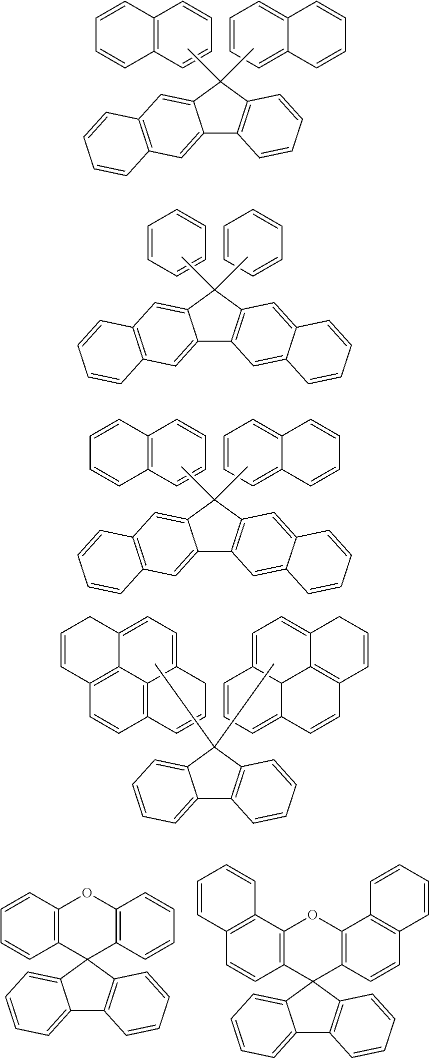

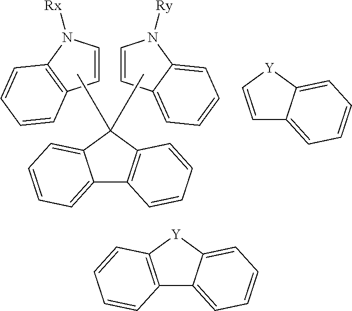

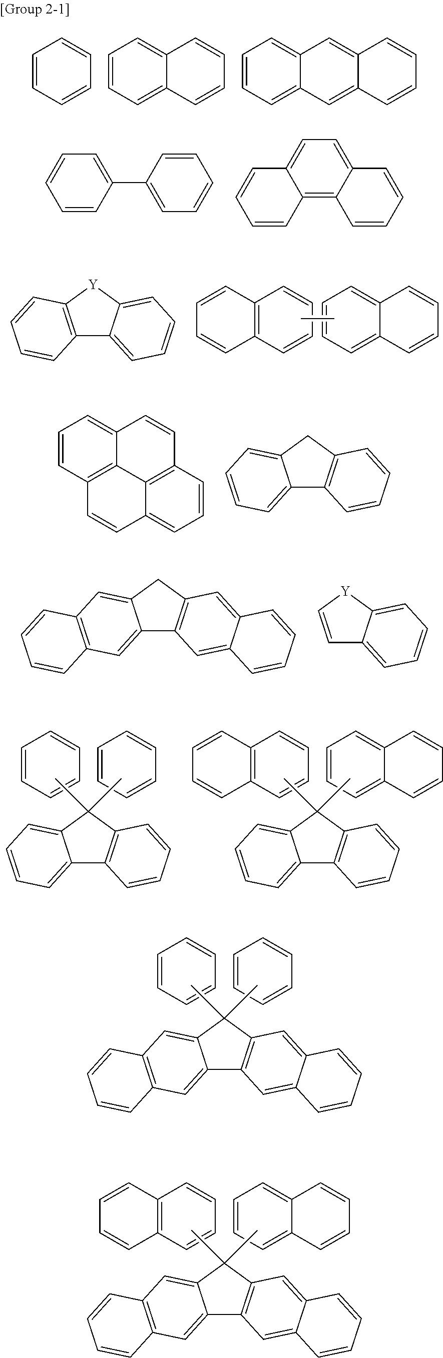

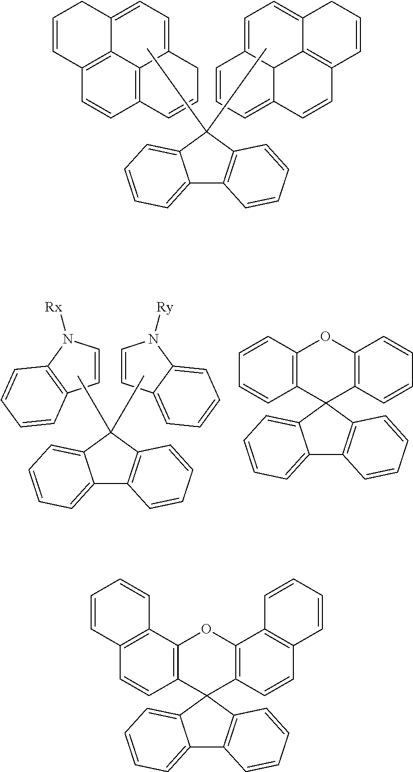

In Group 2 and Group 2-1, Y may be, e.g., —O—, —S—, or —NR^{b-}, in which R^{b} is hydrogen, a substituted or unsubstituted C1 to C10 alkyl group, or a substituted or unsubstituted C6 to C20 aryl group.

Rx and Ry may each independently be, e.g., hydrogen, deuterium, a halogen atom, a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C20 aryl group, and for example Rx and Ry may each independently be hydrogen, deuterium, a substituted or unsubstituted C1 to C10 alkyl group, or a substituted or unsubstituted C6 to C20 aryl group.

In an implementation, Ar¹ of Chemical Formula 1 may be a group that is substituted with, e.g., a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, a substituted or unsubstituted C1 to C20 heteroalkyl group, a substituted or unsubstituted C3 to C20 heteroaryl group, or a combination thereof, for example Ar¹ of Chemical Formula 1 may be substituted with a hydroxy group, a substituted or unsubstituted C1 to C20 alkoxy group, a substituted or unsubstituted C1 to C20 alkyl group, a substituted or unsubstituted C1 to C20 heteroalkyl group, or a substituted or unsubstituted C6 to C20 aryl group. In an implementation, Ar¹ of Chemical Formula 1 may be a group substituted with, e.g., a hydroxy group, a substituted or unsubstituted C1 to C10 alkoxy group, a substituted or unsubstituted C1 to C10 alkyl group, or a substituted or unsubstituted C1 to C10 heteroalkyl group. In an implementation, Ar¹ of Chemical Formula 1 may be a group substituted with, e.g., a hydroxy group or a substituted or unsubstituted C1 to C3 alkoxy group.

In an implementation, R¹ to R⁴ of Chemical Formula 1 may each independently be, e.g., hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof. In an implementation, R¹ to R⁴ of Chemical Formula 1 may each independently be, e.g., hydrogen, deuterium, a substituted or unsubstituted C1 to C10 alkyl group, a substituted or unsubstituted C6 to C16 aryl group, or a combination thereof. In an implementation, R¹ and R² may not be hydrogen at the same time, R³ and R⁴ may not be hydrogen at the same time.

In an implementation, in Chemical Formula 1, R¹ and R³ may be the same or different from each other, and R² and R⁴ may be the same or different from each other.

In an implementation, Ar² and Ar³ of Chemical Formula 2 may each independently be a substituted or unsubstituted C6 to C20 aromatic hydrocarbon group, e.g., a substituted or unsubstituted group of a moiety of Group 3, a substituted or unsubstituted benzene, a substituted or unsubstituted naphthalene, a substituted or unsubstituted anthracene, a substituted or unsubstituted phenanthrene, or a substituted or unsubstituted pyrene, a substituted or unsubstituted benzene, a substituted or unsubstituted naphthalene, or a substituted or unsubstituted pyrene.

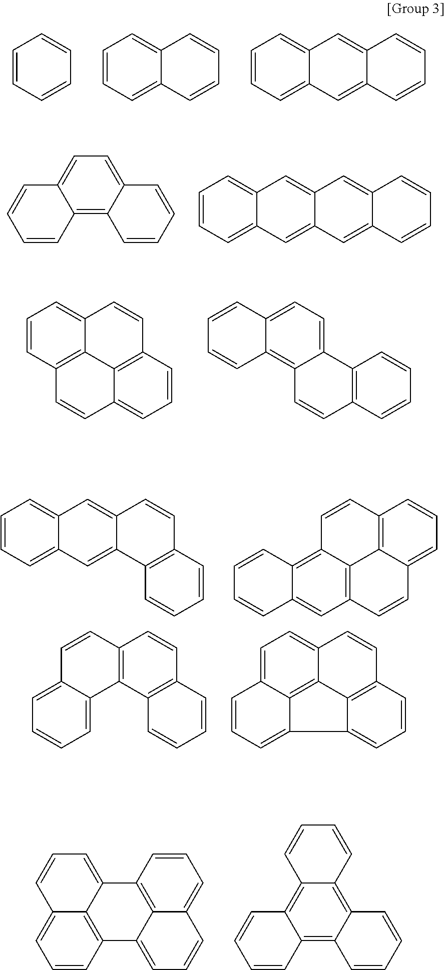

In an implementation, M¹ and M² of Chemical Formula 2 may each independently be, e.g., —O—, —S—, —S(═O)—, —SO₂—, or a combination thereof. In an implementation, M¹ and M² of Chemical Formula 2 may each be, e.g., —O—.

In an implementation, Z of Chemical Formula 2 may be, e.g., a group of Group 1-1, or a group of Group 1-2.

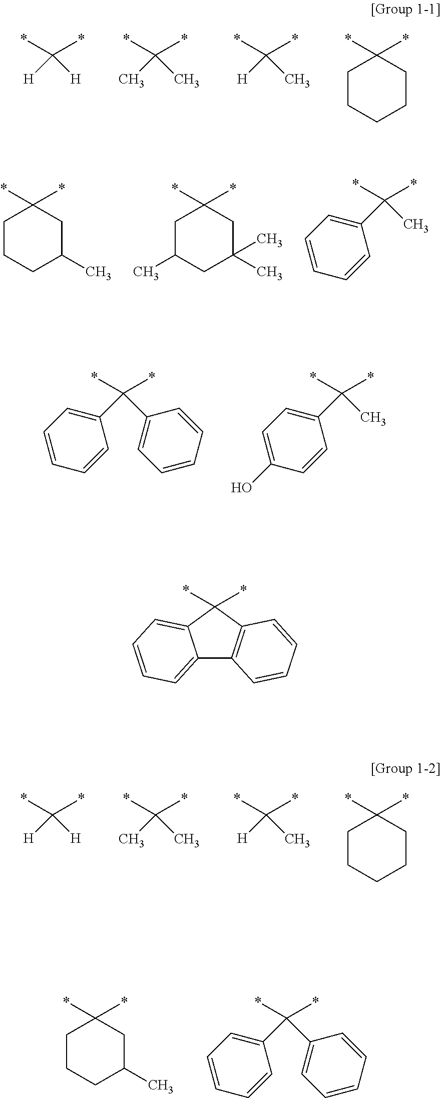

In an implementation, n1 in Chemical Formula 2 may be, e.g., an integer of 1 to 20, an integer of 1 to 10, an integer of 1 to 5, of an integer of 1 to 3.

In an implementation, n1 in Chemical Formula 2 may be, e.g., an integer of 1 to 10, or an integer of 1 to 5 and n2 may be 0. In an implementation, n1 in Chemical Formula 2 may be 1 and n2 may be 1.

In an implementation, the structural unit represented by Chemical Formula 1 may be represented by, e.g., one of Chemical Formula 1-1 to Chemical Formula 1-4.

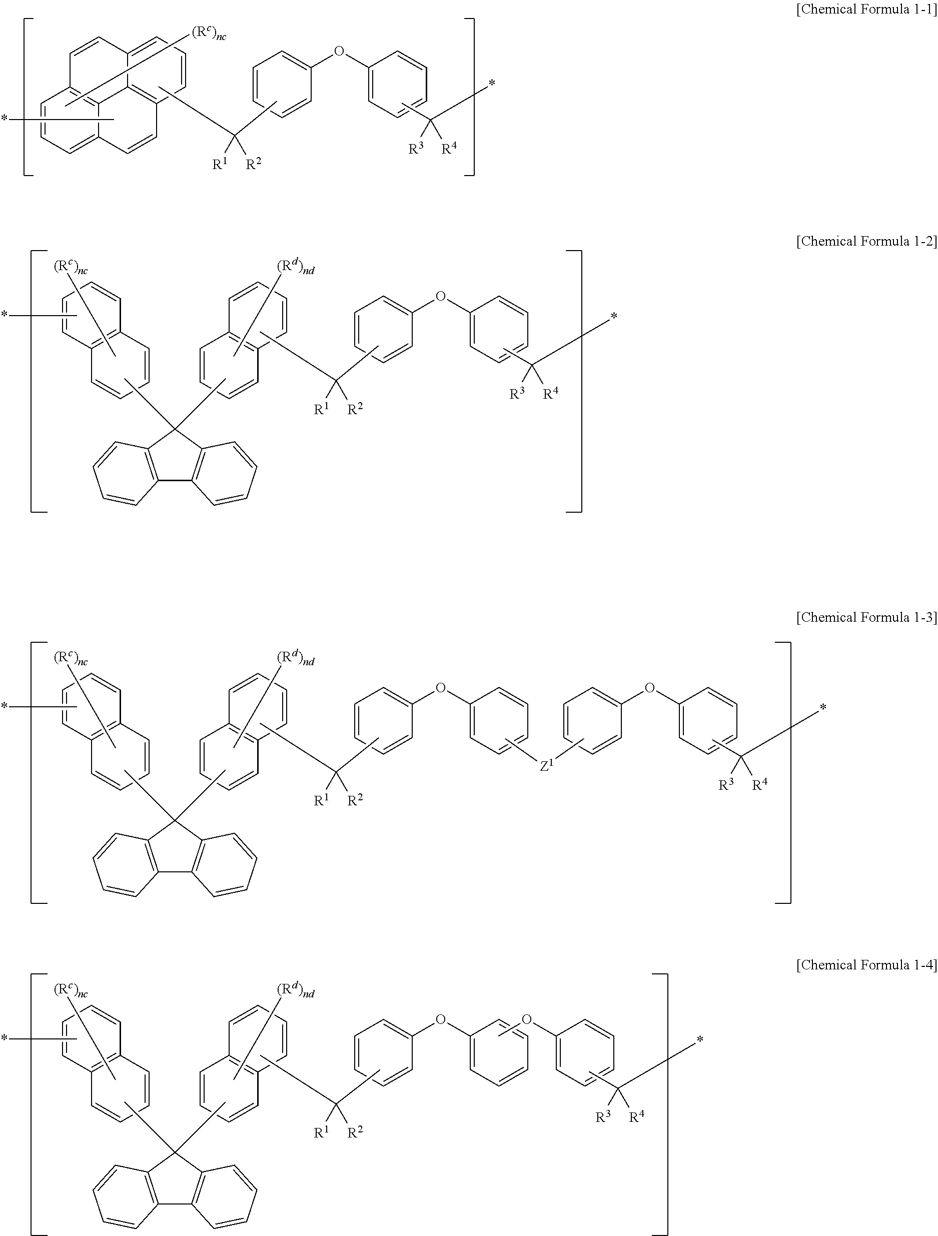

In Chemical Formula 1-1 to Chemical Formula 1-4, R¹ to R⁴ may each independently be, e.g., hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof. In an implementation, R¹ and R² are not hydrogen at the same time and R³ and R⁴ are not hydrogen at the same time.

Z¹ may be, e.g., a group of Group 1.

R^{c} and R^{d} may each independently be, e.g., a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C6 to C20 aryl group, a substituted or unsubstituted C3 to C20 heteroaryl group, or a combination thereof.

nc and nd may each independently be, e.g., an integer of 0 to 6.

In an implementation, the structural unit represented by Chemical Formula 1 may be represented by, e.g., one of Chemical Formula 1-5 to Chemical Formula 1-13.

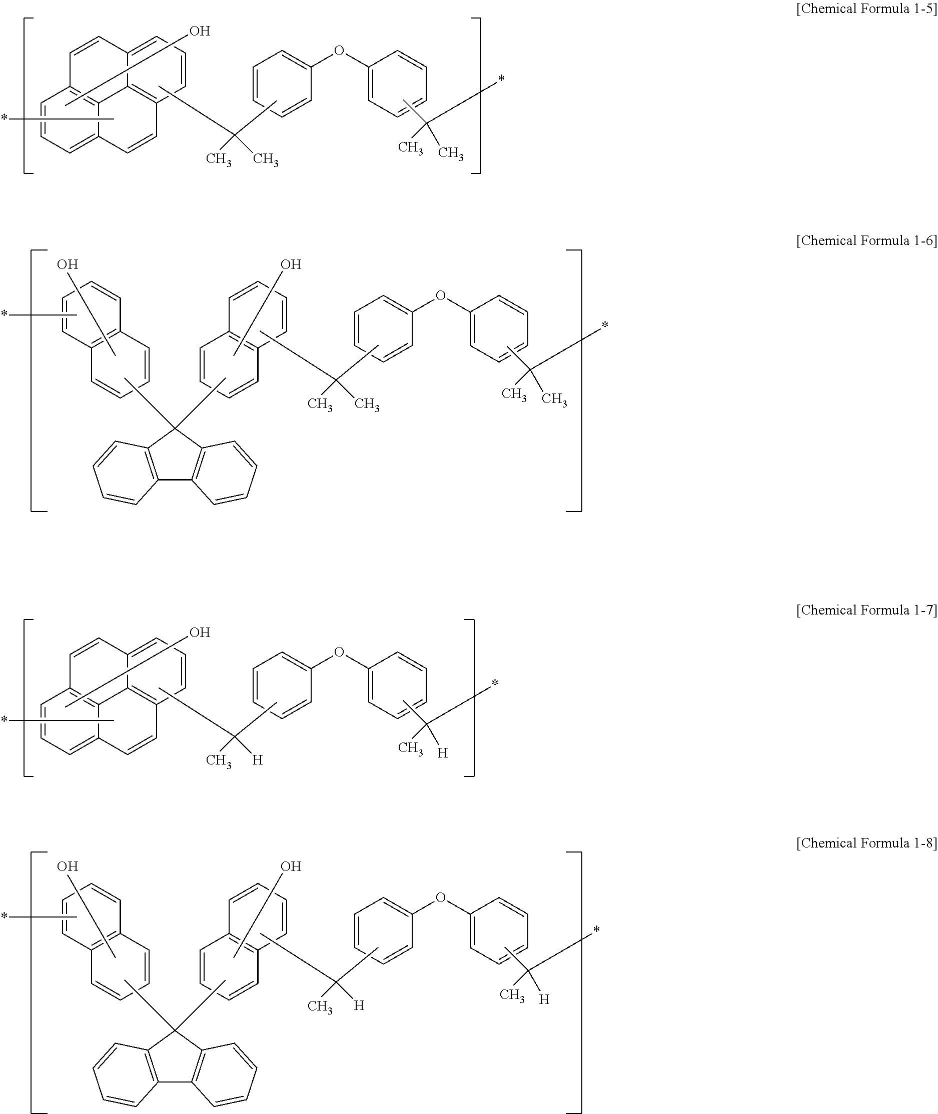

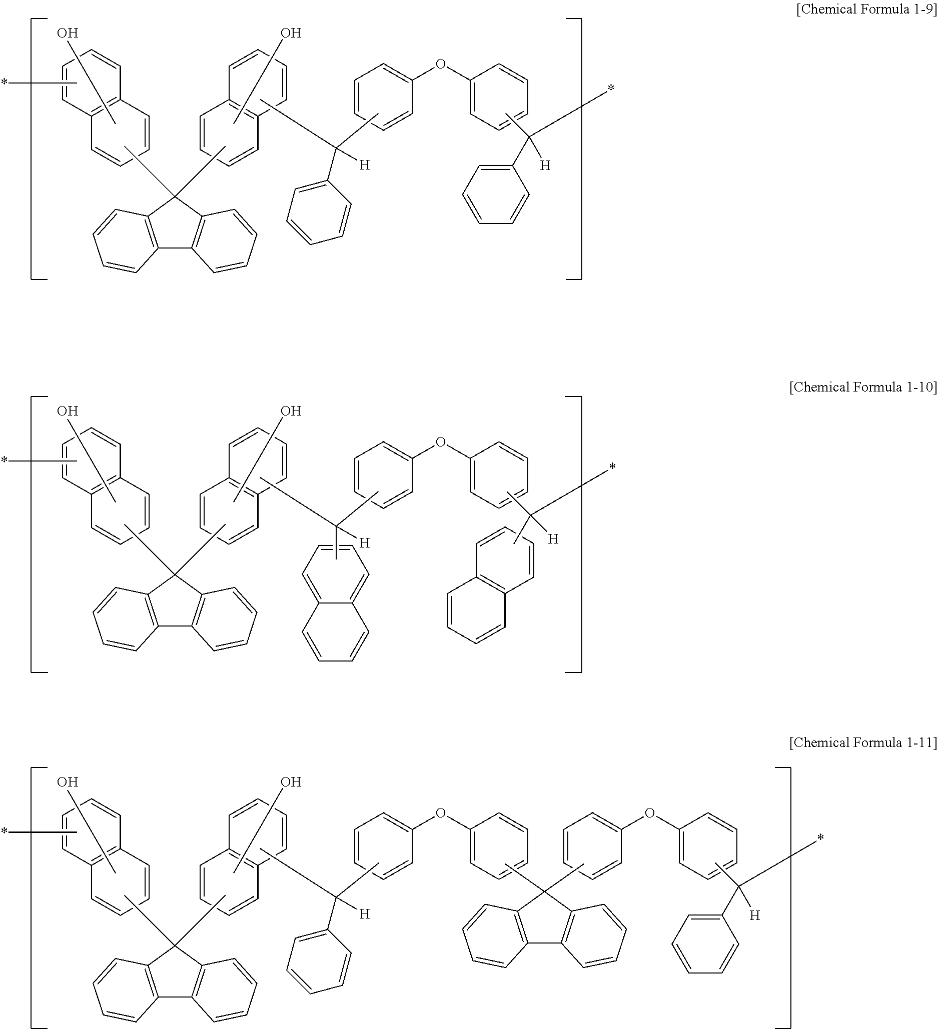

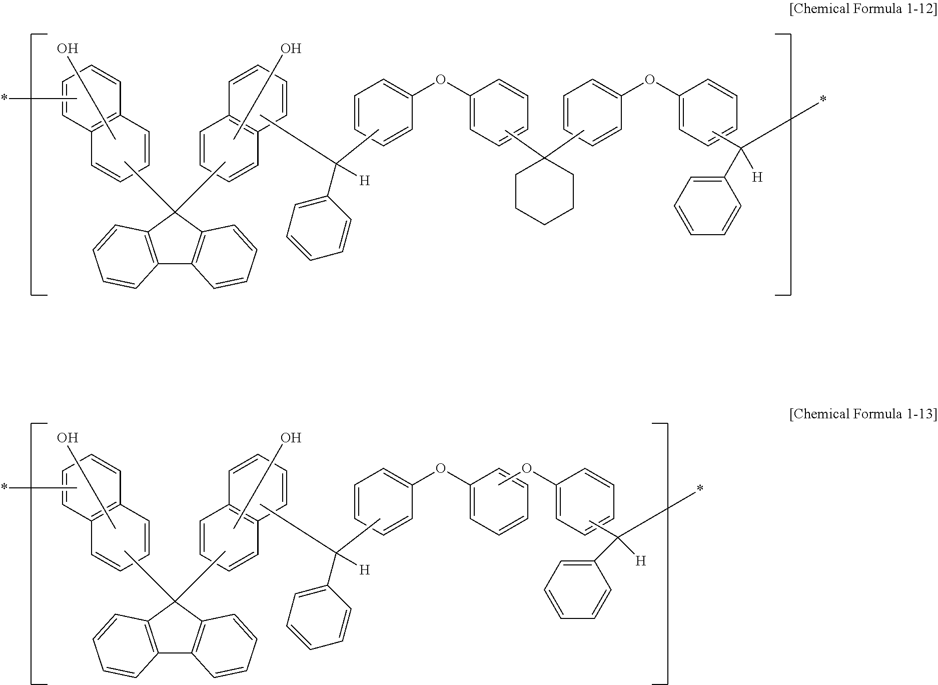

The polymer may have a weight average molecular weight of, e.g., about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,200 g/mol to about 50,000 g/mol, or about 1,200 g/mol to about 10,000 g/mol. By having a weight average molecular weight within the above ranges, the carbon content and solubility in the solvent of the hardmask composition including the above polymer can be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the polymer within the above ranges, a thickness, a surface roughness, and a planarization degree of the hardmask may be easily adjusted.

The hardmask composition may include a solvent, e.g., propylene glycol, propylene glycol diacetate, methoxy propanediol, diethylene glycol, diethylene glycol butyl ether, tri (ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may be a suitable solvent that has sufficient solubility or dispersibility for the polymer.

In an implementation, the hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in the form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 600° C. for about 10 seconds to about 1 hour. In an implementation, the heat-treating may be performed under an atmosphere of air or nitrogen, or an atmosphere having oxygen concentration of about 1 wt % or less.

In an implementation, the heat-treating of the hardmask composition may include, e.g., a first heat-treating process performed at about 100° C. to about 1,000° C., about 100° C. to about 800° C., for example, about 100° C. to about 500° C., or about 150° C. to about 400° C. for about 30 seconds to about 1 hour, about 30 seconds to about 30 minutes, about 30 seconds to about 10 minutes, or 30 seconds to about 5 minutes.

In an implementation, the heat-treating may include a second heat-treating process that is consecutively performed, e.g., at about 100° C. to about 1,000° C., for about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to 5 minutes. In an implementation, the first and second heat-treating processes may be performed under an air or nitrogen atmosphere, or may be performed in an atmosphere with an oxygen concentration of about 1 wt % or less.

By performing at least one of the steps of heat-treating the hardmask composition at a high temperature of, e.g., 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include, e.g., a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may include, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may be, e.g., N₂/O₂, CHF₃, CF₄, Cl₂, BCl₃, or a mixed gas thereof.

The etched material layer may be formed in a plurality of patterns, and the plurality of patterns may be a metal pattern, a semiconductor pattern, an insulation pattern, and the like, for example diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymer

### Synthesis Example 1

(First process) 70.08 g of 4,4′-oxybis(benzoyl chloride) and 350.00 g of tetrahydrofuran were added in a flask to prepare a solution. Subsequently, 79.92 g of methylmagnesium bromide was slowly added to the solution in an ice bath and then, stirred until the 4,4′-oxybis(benzoyl chloride) was all reacted. When the reaction was completed, the resultant was neutralized to about pH 7 by using a 1% hydrogen chloride solution, washed, concentrated under a reduced pressure, and column-purified to obtain Intermediate Product A-1.

(Second process) 37.54 g of Intermediate Product A-1 and 360.00 g of N,N-dimethylformamide were added to the flask to prepare a solution. Subsequently, 9.44 g of sodium hydride was slowly added to the solution at ambient temperature, and 93.03 g of methyl iodide was added thereto and then, stirred until Intermediate Product A-1 was all reacted. When the reaction was completed, the resultant was neutralized to about pH 7 by using a 1% hydrogen chloride solution, washed, concentrated under a reduced pressure, and column-purified to obtain Intermediate Product A-2.

(Third process) 69.80 g of Intermediate Product A-2, 48.45 g of 1-hydroxypyrene, 1.74 g of sulfuric acid, and 80.00 g of propylene glycol methyl ether acetate were added to the flask and then, reacted at 100° C. for 8 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula A. (Mw: 3,082 g/mol)

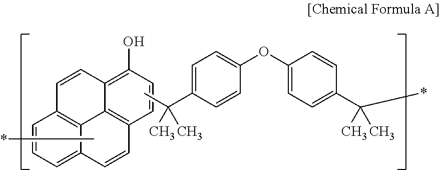

### Synthesis Example 2

48.84 g of Intermediate Product A-2 according to Synthesis Example 1, 48.82 g of 9,9-bis(6-hydroxy-2-naphthyl) fluorene, 1.22 g of sulfuric acid, and 80.00 g of propylene glycol methyl ether acetate were added to a flask and then, reacted at 100° C. for 7 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula B. (Mw: 3,020 g/mol)

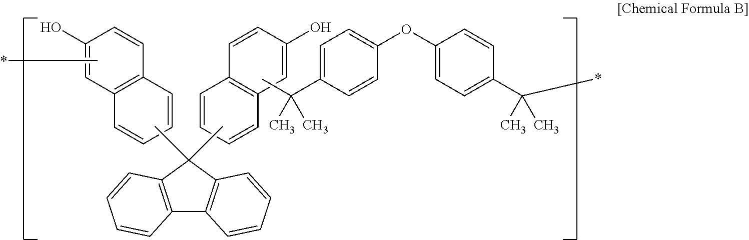

### Synthesis Example 3

(First process) 71.20 g of 4,4′-oxybis(benzoyl chloride) and 350.00 g of tetrahydrofuran were added in a flask to prepare a solution. Subsequently, 78.80 g of methylmagnesium bromide was slowly added to the solution in an ice bath and then, stirred until the 4,4′-oxybis(benzoyl chloride) was all reacted. When the reaction was completed, the resultant was neutralized to about pH 7 by using a 1% hydrogen chloride solution, washed, concentrated under a reduced pressure, and column-purified to obtain Intermediate Product C-1.

(Second process) 37.26 g of Intermediate Product C-1 and 350.00 g of N,N-dimethylformamide were added to the flask to prepare a solution. Subsequently, 10.38 g of sodium hydride was slowly added to the solution at ambient temperature, and 102.36 g of methyl iodide was added thereto and then, stirred until Intermediate Product C-1 was all reacted. When the reaction was completed, the resultant was neutralized to about pH 7 by using a 1% hydrogen chloride solution, washed, concentrated under a reduced pressure, and column-purified to obtain Intermediate Product C-2.

(Third process) 67.06 g of Intermediate Product C-2, 51.11 g of 1-hydroxypyrene, 1.84 g of sulfuric acid, and 80.00 g of propylene glycol methyl ether acetate were added to the flask and then, reacted at 100° C. for 8 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula C. (Mw: 2,920 g/mol)

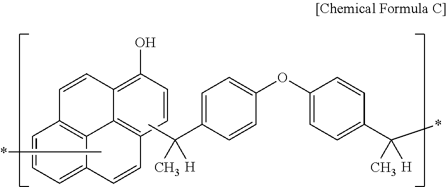

### Synthesis Example 4

46.14 g of Intermediate Product C-2 according to Synthesis Example 3, 72.59 g of 9,9-bis(6-hydroxy-2-naphthyl) fluorene, 1.26 g of sulfuric acid, and 80.00 g of propylene glycol methyl ether acetate were added to a flask and then, reacted at 100° C. for 9 hours, while stirring. When the reaction was completed, the resultant was washed and concentrated under a reduced pressure, and a solid generated by adding n-hexane thereto was extracted/filtered and the, dried under a reduced pressure to obtain a polymer including a structural unit represented by Chemical Formula D. (Mw: 3,020 g/mol)

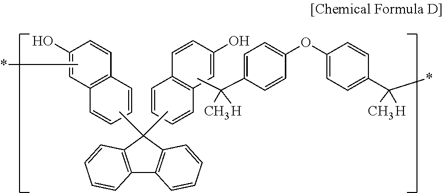

### Synthesis Example 5

(First process) 73.29 g of 4,4′-oxybis(benzoyl chloride) and 350.00 g of tetrahydrofuran were added in a flask to prepare a solution. Subsequently, 96.71 g of phenylmagnesium chloride was slowly added to the solution in an ice bath and then, stirred until the 4,4′-oxybis(benzoyl chloride) was all reacted. When the reaction was completed, the resultant was neutralized to about pH 7 by using a 1% hydrogen chloride solution, washed, concentrated under a reduced pressure, and column-purified to obtain Intermediate Product E-1.

(Second process) 49.28 g of Intermediate Product E-1 and 350.00 g of N,N-dimethylformamide were added to the flask to prepare a solution. Subsequently, 9.28 g of sodium hydride was slowly added to the solution at ambient temperature, and 91.44 g of methyl iodide was added thereto and then, stirred, until Intermediate Product E-1 was all reacted. When the reaction was completed, the resultant was neutralized to about pH 7 by using a 1% hydrogen chloride solution, washed, concentrated under a reduced pressure, and column-purified to obtain Intermediate Product E-2

(Third process) 56.69 g of Intermediate Product E-2, 62.22 g of 9,9-bis(6-hydroxy-2-naphthyl) fluorene, 1.08 g of sulfuric acid, and 80.00 g of propylene glycol methyl ether acetate were added to the flask and then, reacted at 100° C. for 8 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula E. (Mw: 3,120 g/mol)

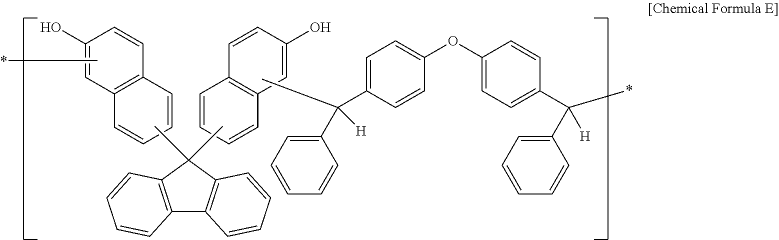

### Synthesis Example 6

(First process) 36.87 g of 4,4′-oxybis(benzaldehyde) and 350.00 g of tetrahydrofuran were added in a flask to prepare a solution. Subsequently, 113.13 g of 2-naphthylmagnesium bromide was slowly added to the solution in an ice bath and then, stirred until the 4,4′-oxybis(benzoyl chloride) was all reacted. When the reaction was completed, the resultant was neutralized to about pH 7 by using a 1% hydrogen chloride solution, washed, concentrated under a reduced pressure, and column-purified to obtain Intermediate Product F-1.

(Second process) 57.26 g of Intermediate Product F-1 and 360.00 g of N,N-dimethylformamide were added to the flask to prepare a solution. Subsequently, 8.54 g of sodium hydride was slowly added to the solution at ambient temperature, and 84.20 g of methyl iodide was added thereto and then, stirred until Intermediate Product F-1 was all reacted. When the reaction was completed, the resultant was neutralized to about pH 7 by using a 1% hydrogen chloride solution, washed, concentrated under a reduced pressure, and column-purified to obtain Intermediate Product F-2.

(Third process) 63.23 g of Intermediate Product F-2, 55.79 g of 9,9-bis(6-hydroxy-2-naphthyl) fluorene, 0.97 g of sulfuric acid, and 80.00 g of propylene glycol methyl ether acetate were added to the flask and then, reacted at 100° C. for 12 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula F. (Mw: 2,890 g/mol)

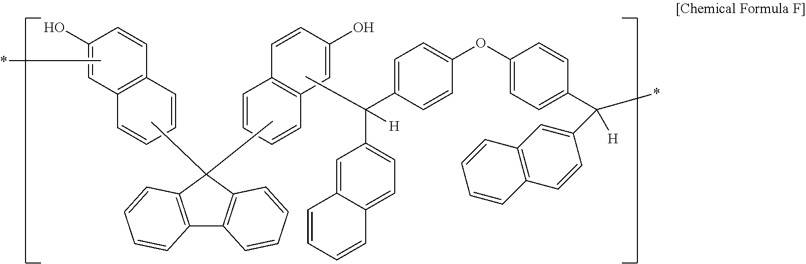

### Synthesis Example 7

(First process) 70.33 g of 9,9-bis(4-hydroxyphenyl) fluorene, 50.32 g of 4-fluorobenzaldehyde, 69.35 g of potassium carbonate, and 310.00 g of N,N-dimethylformamide were added in a flask to prepare a solution. Subsequently, the solution was stirred at 140° C. until the 9,9-bis(4-hydroxyphenyl) fluorene was all reacted. When the reaction was completed, the resultant was neutralized to about pH 7 by using a 1% hydrogen chloride solution, washed, concentrated under a reduced pressure, and column-purified to obtain Intermediate Product G-1.

(Second process) 66.89 g of Intermediate Product G-1 and 350.00 g of tetrahydrofuran were added to the flask to prepare a solution. Subsequently, 83.11 g of phenylmagnesium chloride was slowly added to the solution in an ice bath and then, stirred, until Intermediate Product G-1 was all reacted. When the reaction was completed, the resultant was neutralized to about pH 7 by using a 1% hydrogen chloride solution, washed, concentrated under a reduced pressure, and column-purified to obtain Intermediate Product G-2.

(Third process) 71.65 g of Intermediate Product G-2 and 350.00 g of N,N-dimethylformamide were added to the flask to prepare a solution. Subsequently, 7.22 g of sodium hydride was added to the solution at ambient temperature and then, stirred at 60° C. for 2 hours. After the stirring, 71.13 g of methyl iodide was added thereto at ambient temperature and then, stirred until Intermediate Product G-2 was all reacted. When the reaction was completed, the resultant was neutralized to about pH 7 by using a 1% hydrogen chloride solution, washed, concentrated under a reduced pressure, and column-purified to obtain Intermediate Product G-3.

(Fourth process) 74.21 g of Intermediate Product G-3, 45.01 g of 9,9-bis(6-hydroxy-2-naphthyl) fluorene, 0.78 g of sulfuric acid, and 80.00 g of Propylene glycol methyl ether acetate were added to the flask and then, reacted at 110° C. for 29 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula G. (Mw: 2,996 g/mol)

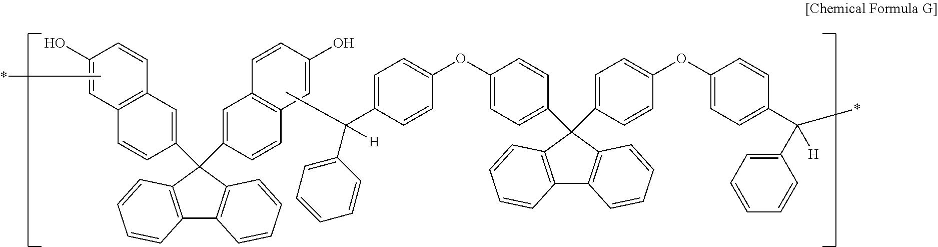

### Synthesis Example 8

(First process) 58.98 g of 4,4′-cyclohexylidenebisphenol, 55.10 g of 4-fluorobenzaldehyde, 75.93 g of potassium carbonate, and 310.00 g of N,N-dimethylformamide were added in a flask to prepare a solution. Subsequently, the solution was stirred at 140° C., until the 4,4′-cyclohexylidenebisphenol was all reacted. When the reaction was completed, the resultant was neutralized to about pH 7 by using a 1% hydrogen chloride solution, washed, concentrated under a reduced pressure, and column-purified to obtain Intermediate Product H-1.

(Second process) 61.06 g of Intermediate Product H-1 and 350.00 g of tetrahydrofuran were added to the flask to prepare a solution. Subsequently, 88.94 g of phenylmagnesium chloride was slowly added to the solution in an ice bath, and 93.03 g of methyl iodide was added thereto and then, stirred until Intermediate Product H-1 was all reacted. When the reaction was completed, the resultant was neutralized to about pH 7 by using a 1% hydrogen chloride solution, washed, concentrated under a reduced pressure, and column-purified to obtain Intermediate Product H-2.

(Third process) 67.10 g of Intermediate Product H-2 and 350.00 g of N,N-dimethylformamide were added to the flask to prepare a solution. Subsequently, 7.64 g of sodium hydride was slowly added to the solution at ambient temperature, and 75.26 g of methyl iodide was added thereto and then, stirred until Intermediate Product H-2 is all reacted. When the reaction was completed, the resultant was neutralized to about pH 7 by using a 1% hydrogen chloride solution, washed, concentrated under a reduced pressure, and column-purified to obtain Intermediate Product H-3.

(Fourth process) 48.31 g of 9,9-bis(6-hydroxy-2-naphthyl) fluorene, 0.84 g of sulfuric acid, and 80.00 g of propylene glycol methyl ether acetate were added to the flask and then, reacted at 100° C. for 8 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula H. (Mw: 3,102 g/mol)

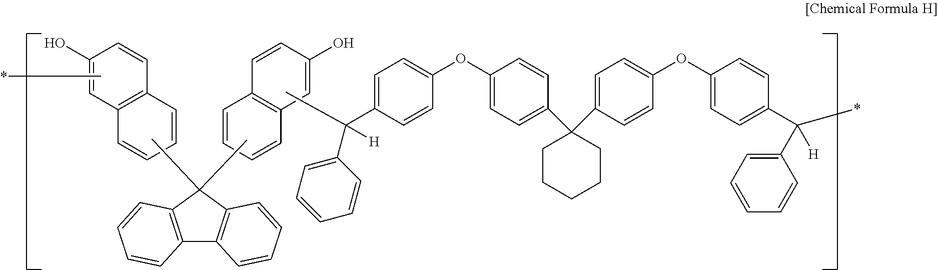

### Synthesis Example 9

(First process) 29.62 g of 1,4-dihydroxybenzene, 67.44 g of 4-fluorobenzaldehyde, 92.94 g of potassium carbonate, and 310.00 g of N,N-dimethylformamide were added to a flask to prepare a solution. The solution was stirred at 140° C., until 1,4-dihydroxybenzene was all reacted. When the reaction was completed, the resultant was neutralized to about pH 7 by using a 1% hydrogen chloride solution, washed, concentrated under a reduced pressure, and column-purified to obtain Intermediate Product I-1.

(Second process) 47.16 g of Intermediate Product I-1 and 350.00 g of tetrahydrofuran were added to the flask to prepare a solution. Subsequently, 102.84 g of phenylmagnesium chloride was slowly added to the solution in an ice bath and then, stirred, until Intermediate Product I-1 was all reacted. When the reaction was completed, the resultant was neutralized to about pH 7 by using a 1% hydrogen chloride solution, washed, concentrated under a reduced pressure, and column-purified to obtain Intermediate Product I-2.

(Third process) 56.66 g of Intermediate Product I-2 and 350.00 g of N,N-dimethylformamide were added to the flask to prepare a solution. Subsequently, 8.60 g of sodium hydride was slowly added to the solution at ambient temperature, and 84.74 g of methyl iodide was added thereto and then, stirred, until Intermediate Product I-2 was all reacted. When the reaction was completed, the resultant was neutralized to about pH 7 by using a 1% hydrogen chloride solution, washed, concentrated under a reduced pressure, and column-purified to obtain Intermediate Product I-3.

(Fourth process) 62.76 g of Intermediate Product I-3, 56.26 g of 9,9-bis(6-hydroxy-2-naphthyl) fluorene, 0.98 g of sulfuric acid, and 80.00 g of propylene glycol methyl ether acetate were added to the flask and then, reacted at 100° C. for 9 hours, while stirring. When the reaction was completed, the resultant was washed and concentrated under a reduced pressure, and a solid generated by adding n-hexane thereto was extracted/filtered and then, dried under a reduced pressure to obtain a polymer including a structural unit represented by Chemical Formula 1. (Mw: 3,084 g/mol)

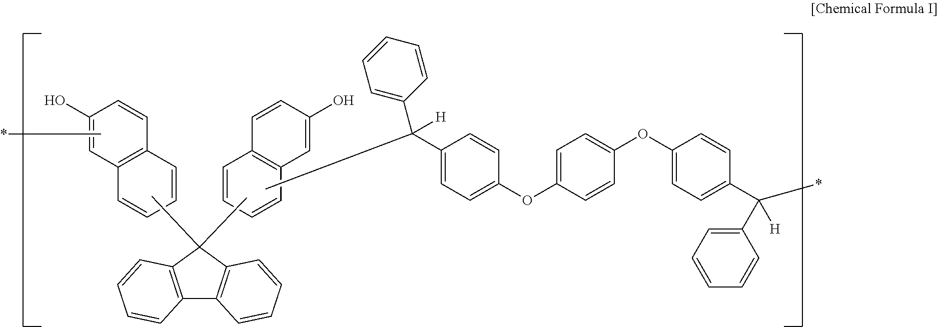

### Comparative Synthesis Example

75.44 g of 9,9-bis(6-hydroxy-2-naphthyl) fluorene, 46.25 g of 4,4′-bis(methoxymethyl)benzene, 1.31 g of sulfuric acid, and 80.00 g of propylene glycol methyl ether acetate were added to a flask and then, reacted at 100° C. for 10 hours. When the reaction was completed, the resultant was washed, concentrated under a reduced pressure, and a solid generated by adding n-hexane thereto was extracted/filtered and then, dried under a reduced pressure to obtain a polymer including a structural unit represented by Chemical Formula J. (Mw: 3,010 g/mol)

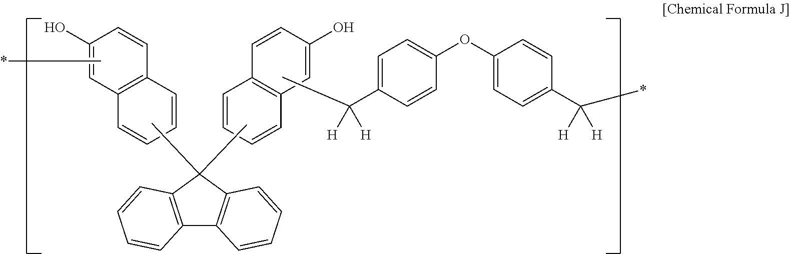

### Preparation of Hardmask Compositions

### Examples and Comparative Examples

Each of the polymers according to Synthesis Examples 1 to 9 and the comparative polymer according to the Comparative Synthesis Example were dissolved in cyclohexanone and filtered with a 0.1 μm membrane filter to prepare a hardmask composition having 10.0 wt % of a compound content.

### Evaluation 1: Gap-filling Characteristics

Each of the hardmask compositions according to Examples 1 to 9 and the Comparative Example 1 was respectively spin-coated on a patterned silicon wafer and then, heat-treated at 400° C. for 60 seconds to form a hardmask layer. A pattern cross-section image of the hardmask layer was examined with a field emission scanning electron microscope (FE-SEM) to check whether voids were generated. The results are shown in Table 1.

TABLE 1

| | Whether voids |
|---|---|
| | occurred |
| Example 1 | No voids |
| Example 2 | No voids |
| Example 3 | No voids |
| Example 4 | No voids |
| Example 5 | No voids |
| Example 6 | No voids |
| Example 7 | No voids |
| Example 8 | No voids |
| Example 9 | No voids |
| Comparative | No voids |
| Example 1 | |

Referring to Table 1, the hardmask layers formed of the hardmask compositions of the Examples and the Comparative Example all exhibit no voids, e.g., the hardmask compositions of the Examples and the Comparative Example all exhibited excellent gap-filling characteristics.

### Evaluation 2: Planarization Characteristics

Each of the hardmask compositions according to Examples 1 to 9 and Comparative Example 1 was spin coated on a patterned silicon wafer and then, heat-treated at 400° C. for 60 seconds, and then, a pattern cross-section image thereof was examined with a field emission scanning electron microscope (FE-SEM). A thickness of each of the hardmask layers on the pattern cross-section image was measured and used to quantify flatness according to Calculation Equation of the FIGURE. In the FIGURE, h₁ indicates an average thickness of three thickness measurements obtained at any three points in a nonpatterned region of the hardmask layer, and h₂ indicates an average thickness of three thickness measurements obtained at any three points in a patterned region of the hardmask layer. If the flatness results were less then 5, “A” (very good) was given, if greater than or equal to 5 and less than 10, “B” (good) was given, and if greater than or equal to 10, “C” (inferior) was given, and the results are shown in Table 2.

TABLE 2

| | Planarization |
|---|---|
| | characteristics |
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative | B |
| Example 1 | |

Referring to Table 2, the hardmask layers of the hardmask compositions of Examples 1 to 9 exhibited very good flatness, and the hardmask layer of the hardmask composition of the Comparative Example was inferior to the hardmask layers of the hardmask compositions of the Example.

### Evaluation 3: Etch Resistance

Each of the hardmask compositions of Examples 1 to 9 and Comparative Example 1 was spin-coated on a silicon wafer and heat-treated at 400° C. for 60 seconds to form a hardmask layer. The hardmask layer was dry-etched by using CF₄/Ar mixed gas for 30 seconds and then, measured with respect to a hardmask thickness before and after the etching by using a film thickness meter made by K-MAC to calculate a bulk etch rate (BER) according to Calculation Equation 2. A ratio of an etch rate of each of the hardmask compositions of Examples 1 to 9 to that of the hardmask layer formed of the composition of Comparative Example 1 was calculated to evaluate etch resistance. If the ratio of the etch rates was less than 0.95, “A” (very good) was given, greater than or equal to 0.95 and less than 1.00, “B” (good) was given, and greater than or equal to 1.00, “C” (inferior) was given. The results are shown in Table 3.

$$Etch rate ( Å / s ) = ( initial thin film thickness - thin film thickness after etching ) / etching time ( s )$$

TABLE 3

| | Etch resistance |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative | — |
| Example 1 | |

Referring to Table 3, the hardmask layers of the Examples exhibited excellent etch resistance, compared with the hardmask layer of the Comparative Example.

### Evaluation 4: Shrinkage Evaluation

Each of the hardmask compositions of Examples 1 to 9 and Comparative Example 1 was spin-coated on a silicon wafer and then, heat-treated on a hot plate at 160° C. for 1 minute to form a hardmask layer. The hardmask layer was measured with respect to a thickness by using a film thickness meter made by K-MAC. Subsequently, the hardmask layer was heat-treated again at 400° C. for 1 minute and then, measured with respect to a thickness. A thickness difference before and after the heat treatment of the hardmask layer was calculated, and if less than 90% of that of Comparative Example 1, “A” (very good) was given, if greater than or equal to 90% and less than 95%, “B” (good) was given, and if greater than or equal to 95%, “C” (inferior) was given. The results are shown in Table 4.

TABLE 4

| | Shrinkage |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative | — |
| Example 1 | |

Referring to Table 4, the hardmask layers formed from the compositions according to Examples 1 to 9 exhibited a lower shrinkage rate than the hardmask layer formed from the composition according to Comparative Example 1.

The hardmask layers formed of the compositions of Examples 1 to 9 exhibited excellent gap-filling characteristics, planarization characteristics, etch resistance, and shrinkage rate. The hardmask layer formed of the composition of the Comparative Example exhibited excellent gap-filling characteristics and etch resistance but inferior planarization characteristics and shrinkage rate, relative to the hardmask layers formed of the compositions of Examples 1 to 9.

By way of summation and review, there is a constant trend in a semiconductor industry to reduce a size of chips. To respond to this, the line width of the resist patterned in lithography technology may have a size of several tens of nanometers. A height that can withstand the line width of the resist pattern may be limited, and there may be cases where the resist cannot sufficiently withstand the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching. The hard mask layer may have etch resistance to withstand the etching process required for pattern transfer.

Some hardmask layers may be formed using a chemical or physical deposition method and may have low economic efficiency due to a large-scale equipment and a high process cost. A method of forming a hard mask layer by a spin-coating technique has recently been developed. The spin-coating technique may be easier to process than other methods and in addition, may help secure excellent gap-filling characteristics and planarization characteristics of a hardmask layer formed therefrom. In the hardmask layer formed using the spin-coating technique, the required etch resistance may be somewhat lowered. A hardmask composition may be applied using the spin-coating technique, and may help secure equivalent etch resistance to that of the hardmask layer formed in the chemical or physical deposition method.

In order to improve the etch resistance of the hardmask layer, research on maximizing a carbon content of a hardmask composition is being made. As a carbon content of a polymer included in the hardmask composition is maximized, solubility in solvents may tend to decrease. The carbon content maximization of a polymer included in the hardmask composition may not only help improve the etch resistance of the hardmask layer formed of the hardmask composition but may also help secure high solubility of the polymer in the solvents.

According to some embodiments, a hardmask composition may include a compound including a large aromatic hydrocarbon ring, thereby increasing the caron content in the composition. Accordingly, a hardmask layer formed of the composition may help secure excellent etch resistance. In addition, the compound may include tertiary carbon or quaternary carbon, thereby increasing the carbon content in the composition without deteriorating the solubility in solvents.

One or more embodiments may provide a hardmask composition that may be effectively applied to a hardmask layer.

The hardmask composition according to some embodiments may have excellent solubility in solvents and may be effectively applied to a hardmask layer.

A hardmask layer formed from the hardmask composition according to some embodiments may help secure excellent heat resistance and excellent etch resistance.

A hardmask layer formed from the hardmask composition according to some embodiments may help secure excellent gap-filling characteristics and planarization characteristics.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent: 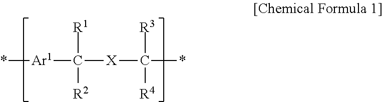
wherein, in Chemical Formula 1,
Ar¹ is a substituted or unsubstituted C6 to C30 aromatic hydrocarbon group, a substituted or unsubstituted C3 to C30 heteroaromatic group, or a group where two or more substituted or unsubstituted C6 to C30 aromatic hydrocarbon groups, two or more substituted or unsubstituted C3 to C30 heteroaromatic groups, or a combination thereof are linked by a single bond or a substituted or unsubstituted C1 to C10 alkylene group,
R¹ to R⁴ are each independently hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic hydrocarbon group, or a combination thereof, provided that R¹ and R² are not hydrogen at the same time and R³ and R⁴ are not hydrogen at the same time, and
X is a group represented by Chemical Formula 2: 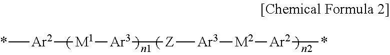
in Chemical Formula 2,
Ar² and Ar³ are each independently a substituted or unsubstituted C6 to C30 aromatic hydrocarbon group, M¹ and M² are each independently —O—, —S—, —S(═O)—, —SO₂—, —NR^{a-}, in which R^{a} is hydrogen, a substituted or unsubstituted C1 to C10 alkyl group, or a substituted or unsubstituted C6 to C20 aryl group, or a combination thereof,
Z is a group of Group 1,
n1 is an integer of 1 to 30,
n2 is 0 or 1, and
* is a linking point:

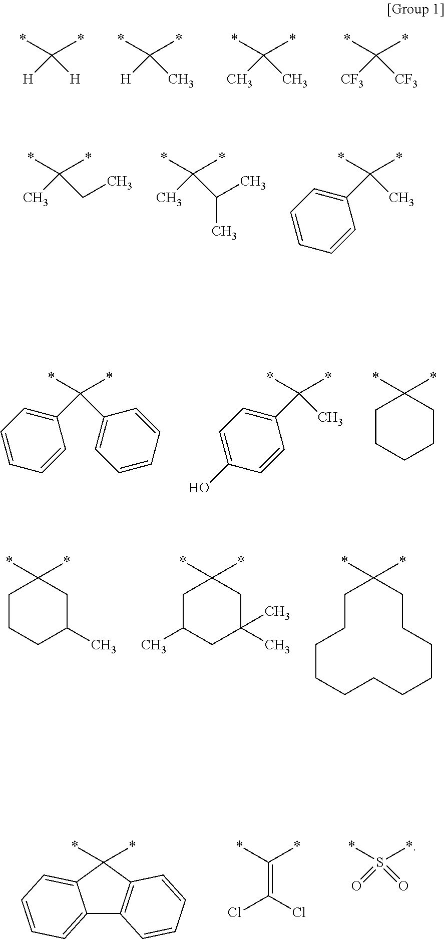

2. The hardmask composition as claimed in claim 1, wherein:
Ar¹ of Chemical Formula 1 is a substituted or unsubstituted group of a moiety of Group 2: 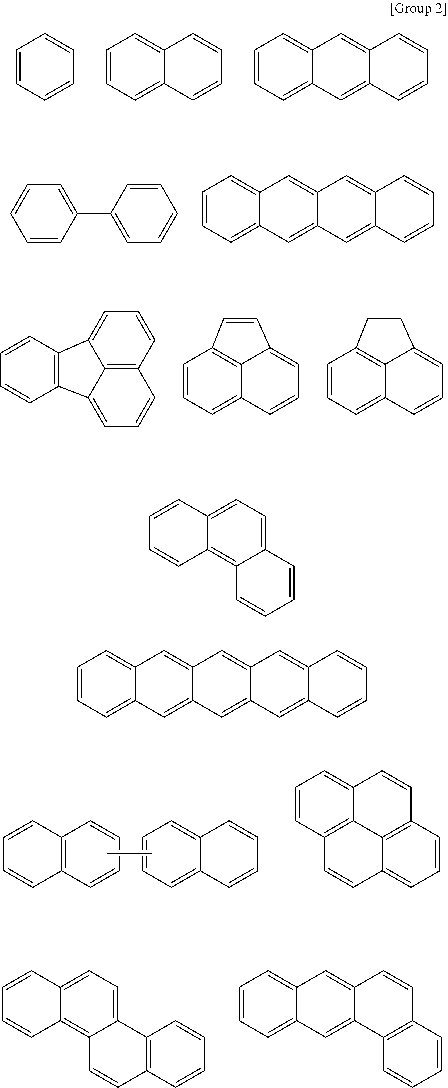 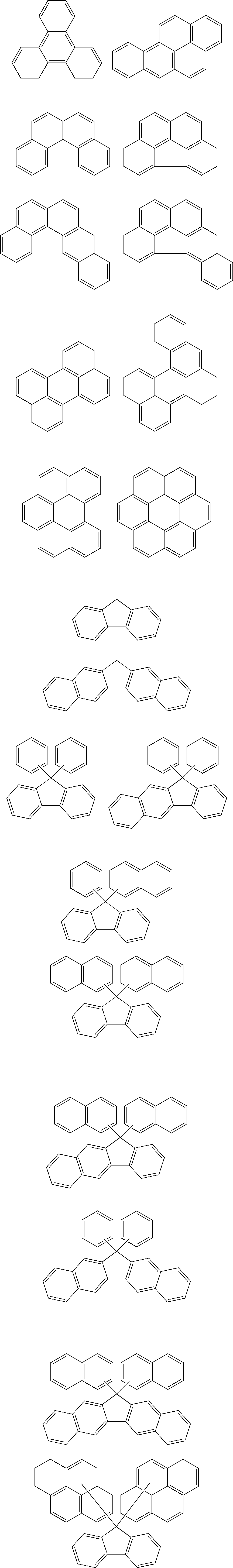 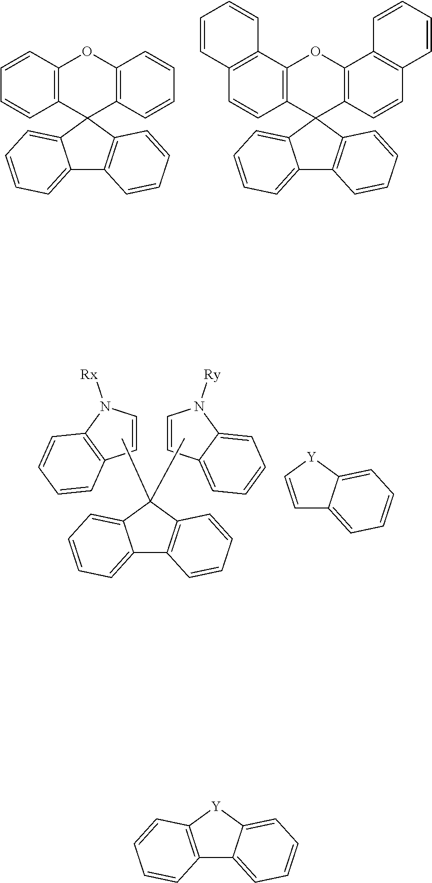
in Group 2,
Y is —O—, —S—, or —NR^{b-}, in which R^{b} is hydrogen, a substituted or unsubstituted C1 to C10 alkyl group, or a substituted or unsubstituted C6 to C20 aryl group, and
Rx and Ry are each independently hydrogen, deuterium, a halogen atom, a substituted or unsubstituted C1 to C10 alkyl group, a substituted or unsubstituted C2 to C10 alkenyl group, a substituted or unsubstituted C2 to C10 alkynyl group, or a substituted or unsubstituted C6 to C20 aryl group.

3. The hardmask composition as claimed in claim 1, wherein:
Ar¹ of Chemical Formula 1 is substituted C6 to C30 aromatic hydrocarbon group, a substituted C3 to C30 heteroaromatic group, or a group where two or more substituted C6 to C30 aromatic hydrocarbon groups, two or more substituted C3 to C30 heteroaromatic groups, or a combination thereof are linked by a single bond or a substituted or unsubstituted C1 to C10 alkylene group, and
a substituent of the substituted C6 to C30 aromatic hydrocarbon group, a substituted C3 to C30 heteroaromatic group, or a group where two or more substituted C6 to C30 aromatic hydrocarbon groups, two or more substituted C3 to C30 heteroaromatic groups, or a combination thereof are linked by a single bond or a substituted or unsubstituted C1 to C10 alkylene group includes a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, a substituted or unsubstituted C1 to C20 heteroalkyl group, a substituted or unsubstituted C3 to C20 heteroaryl group, or a combination thereof.

4. The hardmask composition as claimed in claim 1, wherein R¹ to R⁴ of Chemical Formula 1 are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, provided that R¹ and R² are not hydrogen at the same time and R³ and R⁴ are not hydrogen at the same time.

5. The hardmask composition as claimed in claim 1, wherein in Chemical Formula 1, R¹ and R³ are the same and R² and R⁴ are the same.

6. The hardmask composition as claimed in claim 1, wherein:
Ar¹ of Chemical Formula 1 is a substituted or unsubstituted group of a moiety of Group 2-1, and
R¹ to R⁴ are each independently hydrogen, deuterium, a substituted or unsubstituted C1 to C10 alkyl group, a substituted or unsubstituted C6 to C16 aryl group, or a combination thereof, provided that R¹ and R² are not hydrogen at the same time and R³ and R⁴ are not hydrogen at the same time: 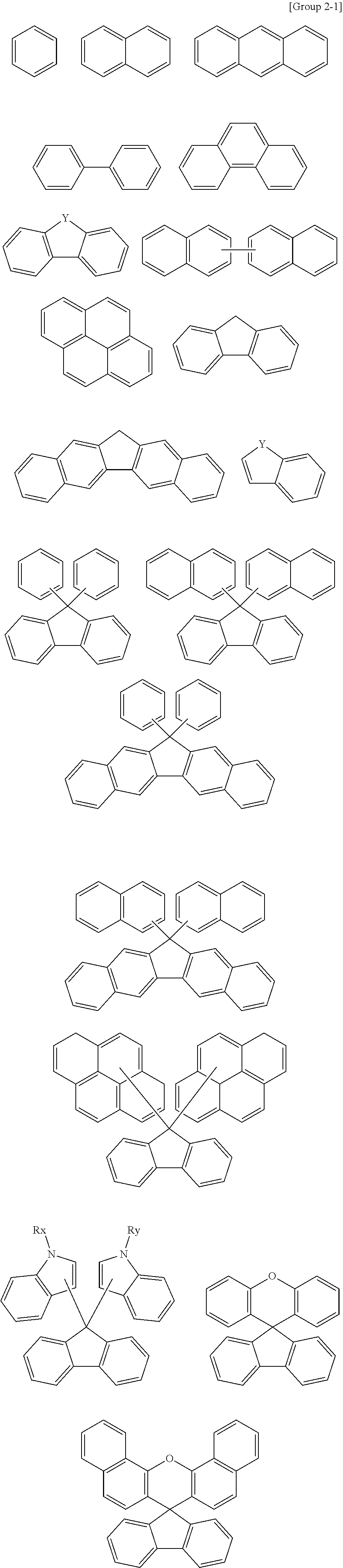
in Group 2-1,
Y is —O—, —S—, or —NR^{b-}, in which R^{b} is hydrogen, a substituted or unsubstituted C1 to C10 alkyl group, or a substituted or unsubstituted C6 to C20 aryl group, and
Rx and Ry are each independently hydrogen, deuterium, a substituted or unsubstituted C1 to C10 alkyl group, or a substituted or unsubstituted C6 to C20 aryl group.

7. The hardmask composition as claimed in claim 1, wherein Ar² and Ar³ of Chemical Formula 2 are each independently a substituted or unsubstituted C6 to C30 aromatic hydrocarbon group of a moiety of Group 3:

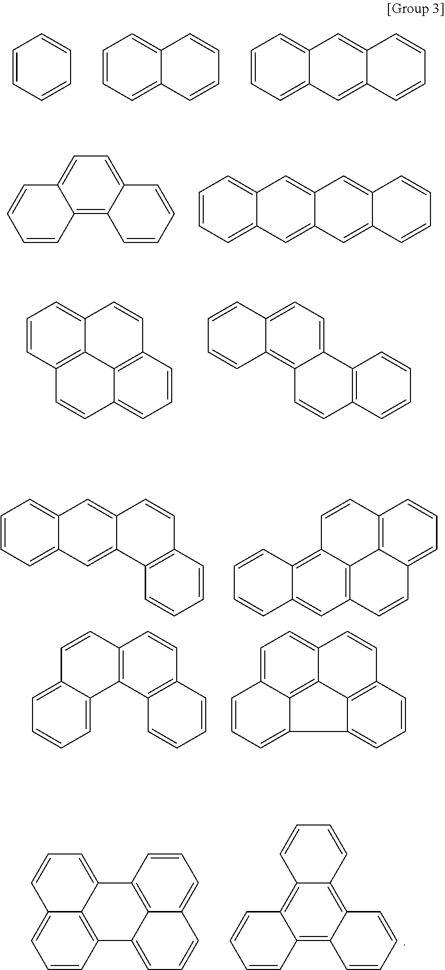

8. The hardmask composition as claimed in claim 1, wherein Ar² and Ar³ of Chemical Formula 2 are each independently a substituted or unsubstituted benzene group, a substituted or unsubstituted naphthalene group, a substituted or unsubstituted phenanthrene group, a substituted or unsubstituted anthracene group, or a substituted or unsubstituted pyrene group.

9. The hardmask composition as claimed in claim 1, wherein:
Ar² and Ar³ of Chemical Formula 2 are each independently substituted or unsubstituted benzene group, substituted or unsubstituted naphthalene group, or substituted or unsubstituted pyrene group,
M¹ and M² are —O—,
n1 is an integer of 1 to 5, and
Z is a group of Group 1-1:

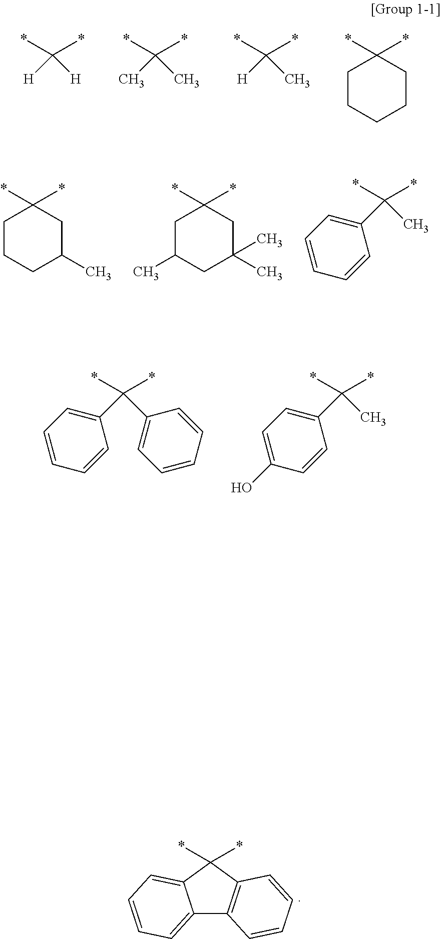

10. The hardmask composition as claimed in claim 1, wherein in Chemical Formula 2, n1 and n2 are each 1.

11. The hardmask composition as claimed in claim 1, wherein in Chemical Formula 2,
n1 is an integer of 1 to 5, and
n2 is 0.

12. The hardmask composition as claimed in claim 1, wherein:
the structural unit represented by Chemical Formula 1 is represented by one of Chemical Formula 1-1 to Chemical Formula 1-4: 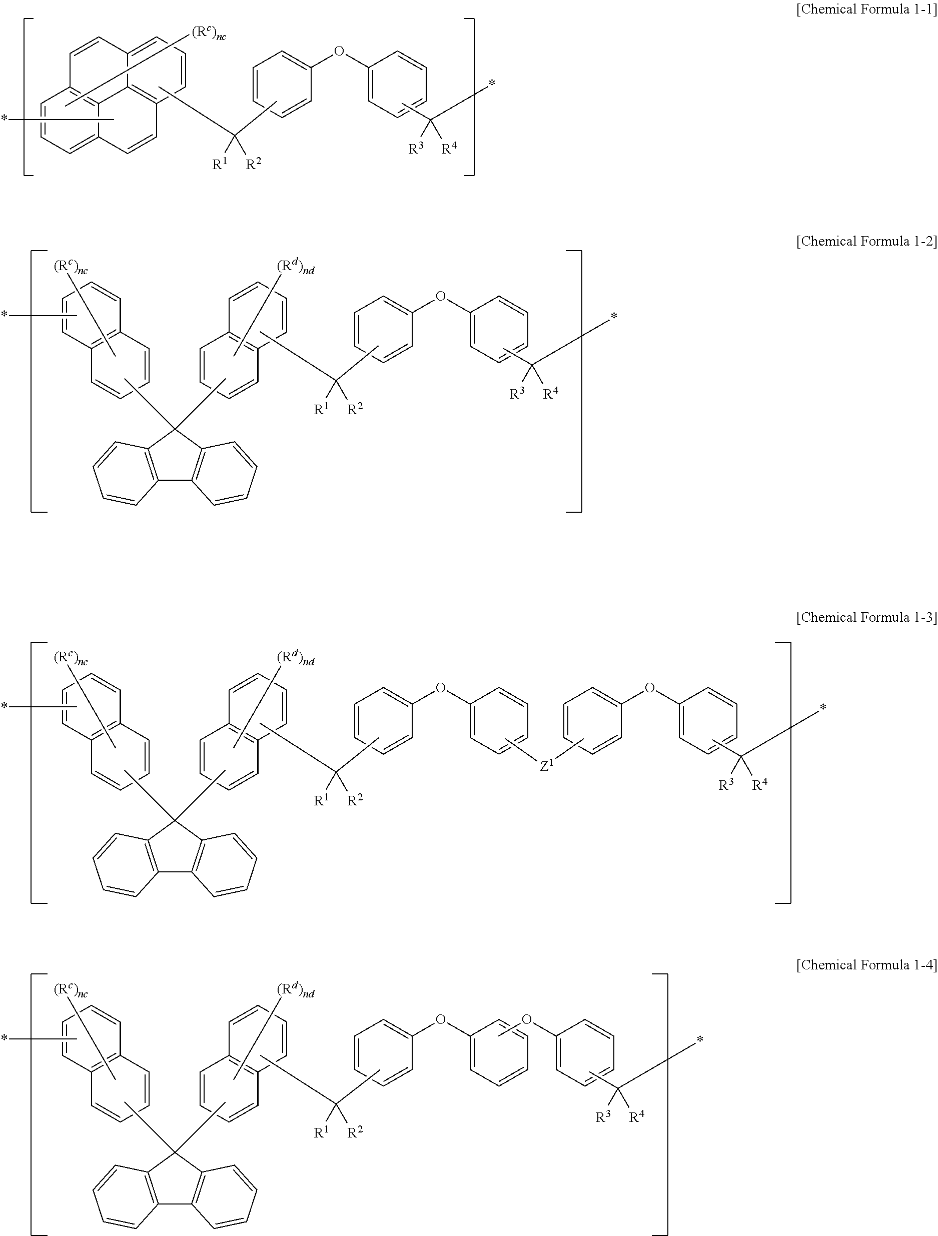
in Chemical Formula 1-1 to Chemical Formula 1-4,
R¹ to R⁴ are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, provided that R¹ and R² are not hydrogen at the same time and R³ and R⁴ are not hydrogen at the same time,
Z¹ is a group of Group 1,
R^{c} and R^{d} are each independently a hydroxy group, a halogen atom, a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C6 to C20 aryl group, a substituted or unsubstituted C3 to C20 heteroaryl group, or a combination thereof, and
nc and nd are each independently an integer of 0 to 6:

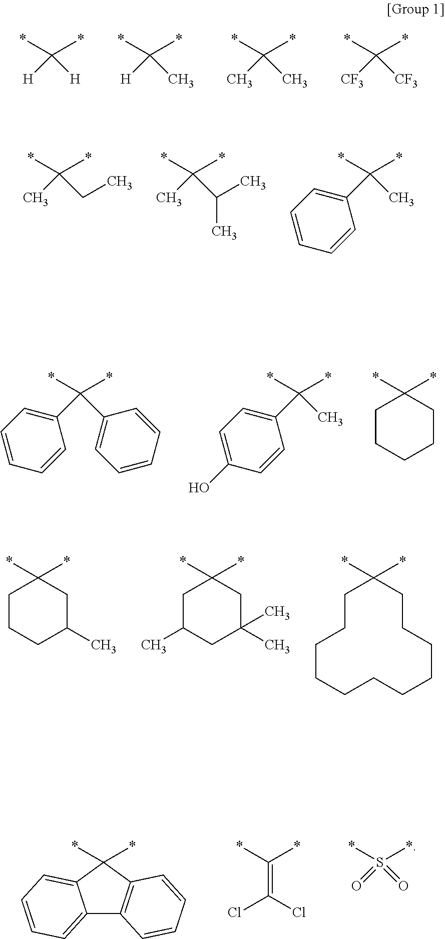

13. The hardmask composition as claimed in claim 1, wherein the structural unit represented by Chemical Formula 1 is represented by one of Chemical Formula 1-5 to Chemical Formula 1-13:

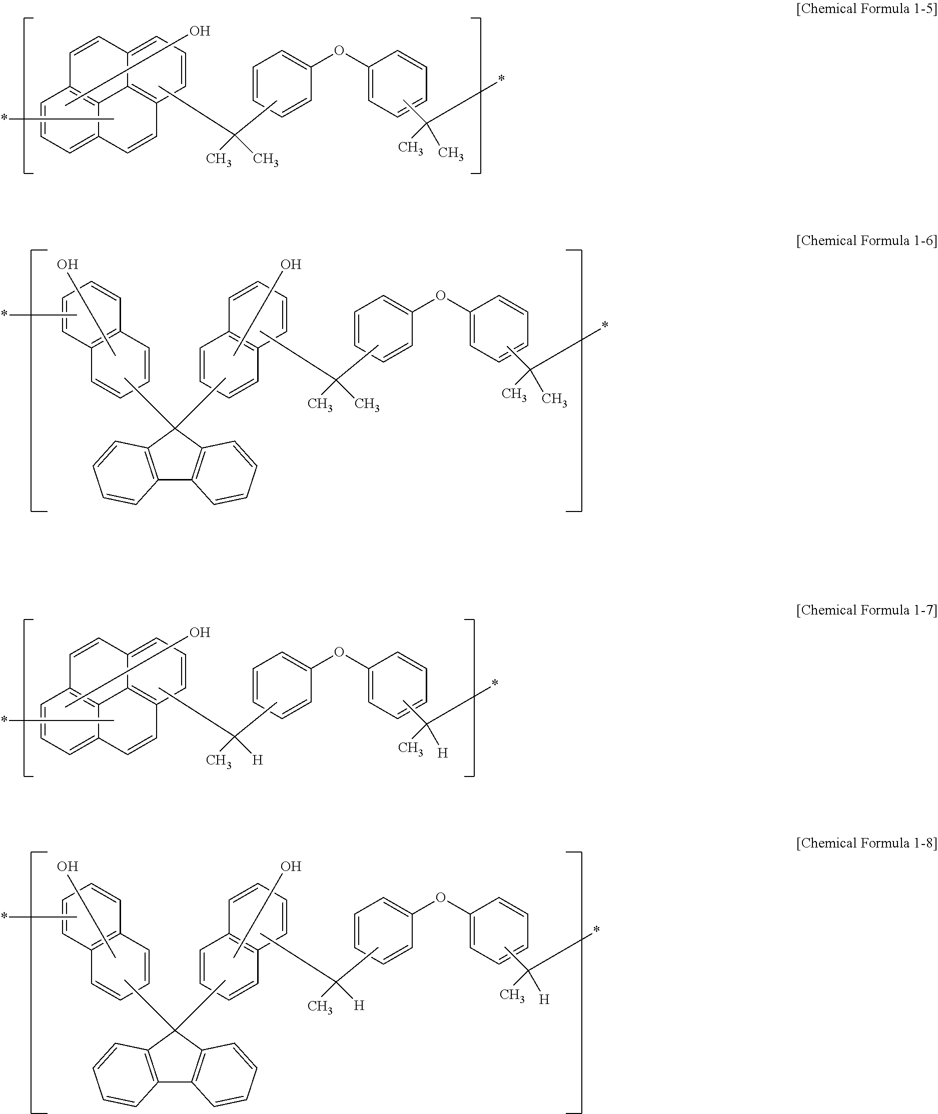

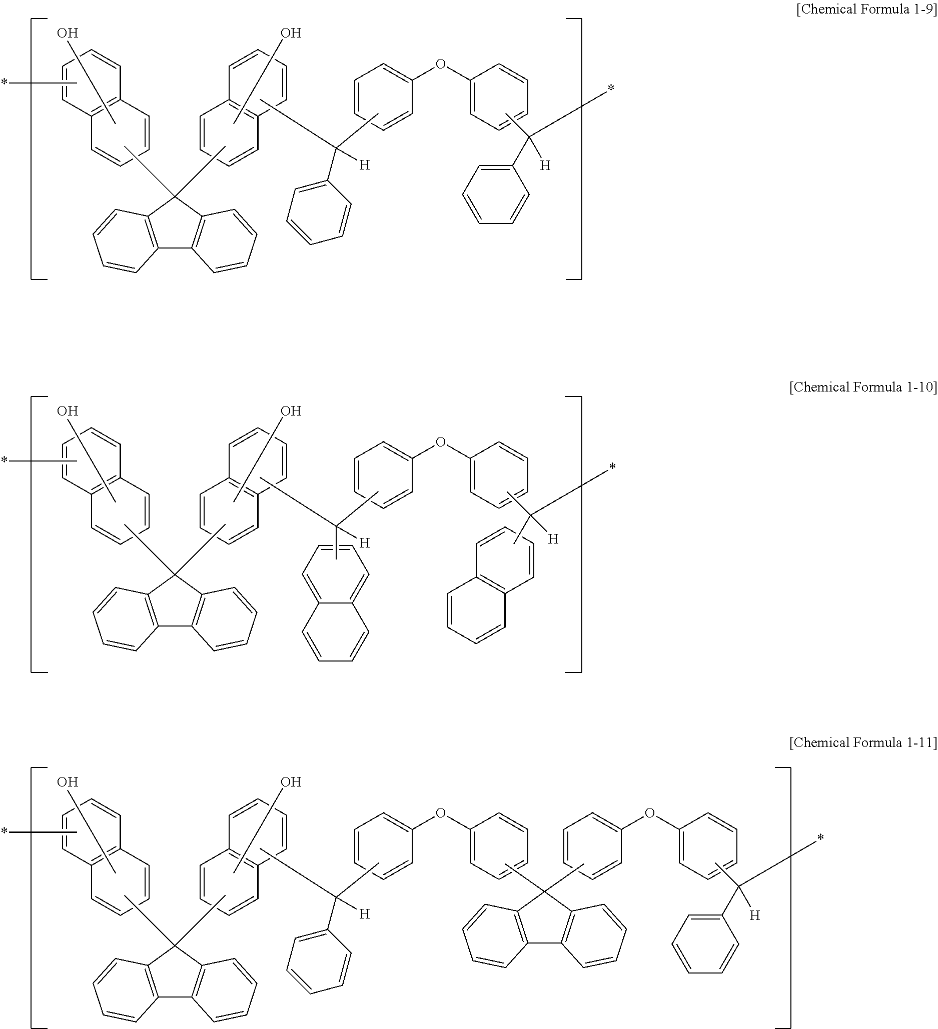

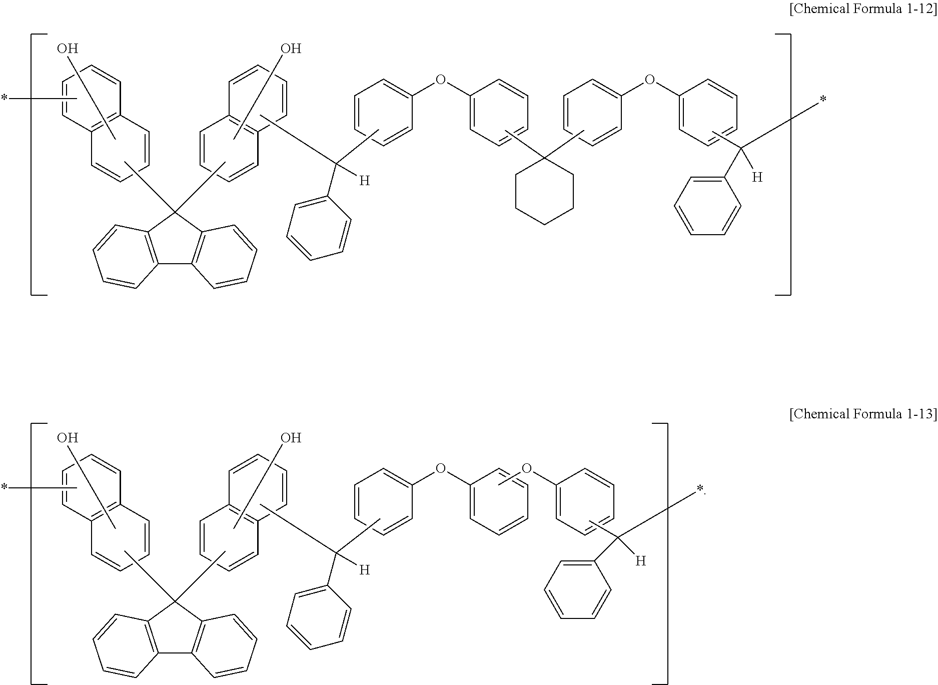

14. The hardmask composition as claimed in claim 1, wherein the polymer has a weight average molecular weight of about 1,000 g/mol to about 200,000 g/mol.

15. The hardmask composition as claimed in claim 1, wherein the polymer is included in an amount of about 0.1 wt % to about 30 wt %, based on a total weight of the hardmask composition.

16. The hardmask composition as claimed in claim 1, wherein the solvent is propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

17. A hardmask layer comprising a cured product of the hardmask composition as claimed in claim 1.

18. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

19. The method as claimed in claim 18, wherein forming the hardmask layer includes heat-treating at about 100° C. to about 1,000° C.
